(19) United States
(12) Patent Application Publication
(10) Pub. No.: US 2026/0047098 A1
(43) Pub. Date: Feb. 12, 2026

(54) SEMICONDUCTOR DEVICE

(71) Applicant: Samsung Electronics Co., Ltd., Suwon-si (KR)

(72) Inventors: Kwangsoo Kim, Suwon-si (KR); Jongho Woo, Suwon-si (KR)

(21) Appl. No.: 19/271,537

(22) Filed: Jul. 16, 2025

(30) Foreign Application Priority Data
Aug. 8, 2024 (KR) 10-2024-0106361

(51) Int. Cl. H10B 51/30; H10B 51/20

(52) U.S. Cl. CPC H10B 51/30; H10B 51/20

(57) ABSTRACT

A semiconductor device may include insulation layer patterns on a substrate, gate patterns, a first interface insulation layer pattern, a ferroelectric layer pattern, and a channel layer pattern. The insulation layer patterns may be spaced apart from each other in a vertical direction perpendicular to a surface of the substrate. The gate patterns may be interposed between the insulation layer patterns in the vertical direction. Each of the gate patterns may have a first portion contacting the insulation layer patterns and a second portion non-contacting the insulation layer patterns. In each of the gate patterns, the second portion may protrude from sidewalls of the insulation layer patterns, and the second portion may have a thickness less than a thickness of the first portion of each of the gate patterns.

### CROSS-REFERENCE TO RELATED APPLICATION

This application claims priority under 35 USC § 119 to Korean Patent Application No. 10-2024-0106361, filed on Aug. 8, 2024, in the Korean Intellectual Property Office KIPO, the contents of which are incorporated by reference herein in their entirety.

### BACKGROUND

Various example embodiments relate to a semiconductor device. Particularly, various example embodiments relate to a vertical memory device in which memory cells are stacked in a vertical direction.

In order to achieve high integration of a semiconductor device, a vertical memory device in which memory cells are stacked in a vertical direction may be presented. In the vertical memory device, a structure including a ferroelectric material in each of the memory cells may be developed.

### SUMMARY

Aspects of various example embodiments provide a semiconductor device including memory cells having excellent operating characteristics.

According to some example embodiments, a semiconductor device may include insulation layer patterns on a substrate, gate patterns, a first interface insulation layer pattern, a ferroelectric layer pattern, and a channel layer pattern. The insulation layer patterns may be spaced apart from each other in a vertical direction perpendicular to a surface of the substrate. The gate patterns may be interposed between the insulation layer patterns in the vertical direction. Each of the gate patterns may have a first portion contacting the insulation layer patterns and a second portion non-contacting the insulation layer patterns. The second portion of each of the gate patterns may protrude from sidewalls of the insulation layer patterns, and the second portion of each of the gate patterns may have a thickness less than a thickness of the first portion of each of the gate patterns. The first interface insulation layer pattern, the ferroelectric layer pattern, and the channel layer pattern sequentially stacked on the sidewalls of the insulation layer patterns and surfaces of the second portions of the gate patterns. The first interface insulation layer pattern, the ferroelectric layer pattern and the channel layer pattern may be disposed along surface profiles of the sidewalls of the insulation layer patterns and the second portions of the gate patterns.

According to some example embodiments, there is provided a semiconductor device. The semiconductor device may include a first stacked structure, a first interface insulation layer pattern and a ferroelectric layer pattern, a channel layer pattern, and an insulation structure. The first stacked structure may include insulation layer patterns and gate patterns alternately and repeatedly disposed on a substrate. The first stacked structure may include a first hole passing through the insulation layer patterns and gate patterns. The first interface insulation layer pattern and the ferroelectric layer pattern may be sequentially stacked along profiles of sidewalls of the insulation layer patterns and surfaces of the gate patterns exposed by the first hole. The channel layer pattern may be on the ferroelectric layer pattern and a bottom of the first hole. Then insulation structure may be on the channel layer pattern to fill the first hole. Each of the gate patterns may include a first portion contacting the insulation layer patterns and a second portion non-contacting the insulation layer patterns, and the second portion may protrude toward an inside of the first hole more than the sidewalls of the insulation layer patterns exposed by the first hole. A boundary between the first portion of a gate pattern and the second portion of the gate pattern may be positioned in a gap between insulation layer patterns.

According to some example embodiments, there is provided a semiconductor device. The semiconductor device may include a source line on a substrate, a stacked structure, a first interface insulation layer pattern, a ferroelectric layer pattern, a channel layer pattern, and an insulation structure. The stacked structure may include insulation layer patterns and gate patterns alternately and repeatedly stacked on the source line, the stacked structure may include an opening passing through the insulation layer patterns and the gate patterns. Each of the gate patterns may include a first portion contacting the insulation layer patterns and a second portion non-contacting the insulation layer patterns. The second portion may protrude toward an inside of the opening more than sidewalls of the insulation layer patterns exposed by the opening. The first interface insulation layer pattern and the ferroelectric layer pattern may be sequentially stacked on the sidewalls of the insulation layer patterns and surfaces of the gate patterns exposed by the opening. The channel layer pattern may be on the ferroelectric layer pattern and a bottom of the opening. The insulation structure may be on the channel layer pattern to fill the opening. A thickness of the second portion of a gate pattern may be less than a thickness of the first portion of the gate pattern, and an edge of the second portion of the gate pattern may have a rounded shape. The first interface insulation layer pattern, the ferroelectric layer pattern and the channel layer pattern may be disposed on the second portion of the gate pattern include protruding portions toward the inside of the opening formed on a surface of the second portion of the gate pattern protruding toward the inside of eh opening.

In the semiconductor device according to example embodiments, the channel layer pattern may surround the second portion of the gate pattern. Therefore, electric fields may not be concentrated at the channel layer pattern. Accordingly, charges trapped at an interface between the channel layer pattern and the ferroelectric layer pattern may be decreased, and thus a difference of threshold voltages between a programming state and an erase state in each of memory cells of the semiconductor device may be increased. Accordingly, the semiconductor device may have excellent operating characteristics.

### BRIEF DESCRIPTION OF THE DRAWINGS

Various example embodiments will be more clearly understood from the following detailed description taken in conjunction with the accompanying drawings. FIGS. 1 to 37 represent various non-limiting, example embodiments as described herein.

FIG. 1 is a vertical cross-sectional view illustrating a vertical semiconductor device according to example embodiments;

FIG. 2 is a cutaway perspective view of a portion of a vertical semiconductor device according to example embodiments;

FIGS. 3 and 4 are horizontal cross-sectional views (plan views) of portions of a vertical semiconductor device according to example embodiments;

FIG. 5 illustrates an energy band of a memory cell of a programmed state in the vertical semiconductor device;

FIG. 6 illustrates an energy band of a memory cell of an erased state in the vertical semiconductor device;

FIG. 7 is a vertical cross-sectional view illustrating a vertical semiconductor device according to example embodiments;

FIG. 8 is a vertical cross-sectional view illustrating a vertical semiconductor device according to example embodiments;

FIG. 9 is a vertical cross-sectional view illustrating a vertical semiconductor device according to example embodiments;

FIGS. 10 to 28 are cross-sectional views and perspective views illustrating a method of manufacturing a vertical semiconductor device according to example embodiments;

FIG. 29 is a perspective view illustrating a vertical semiconductor device according to example embodiments;

FIG. 30 is a horizontal cross-sectional view (a plan view) of a portion of a vertical semiconductor device according to example embodiments; and

FIGS. 31 to 37 are perspective views illustrating a method of manufacturing a vertical semiconductor device according to example embodiments.

### DETAILED DESCRIPTION

Hereinafter, various example embodiments will be described in detail with reference to the accompanying drawings. In the following description, directions parallel to a surface of a substrate and perpendicular to each other are referred to as a first direction and a second direction (or horizontal directions), respectively. In addition, a direction perpendicular to the surface of the substrate is referred to as a vertical direction.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

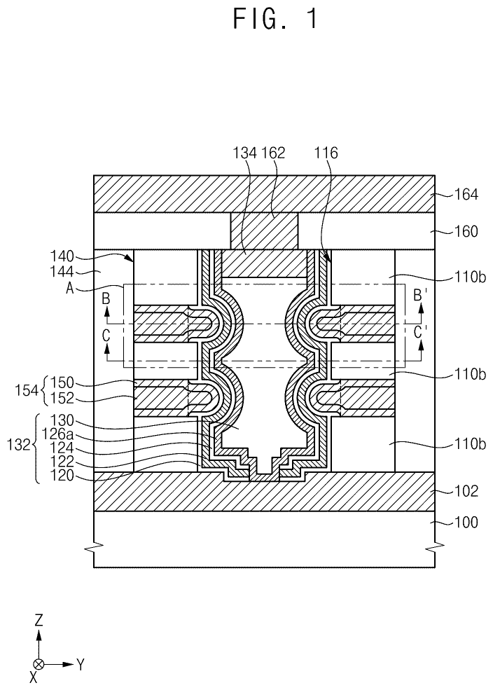

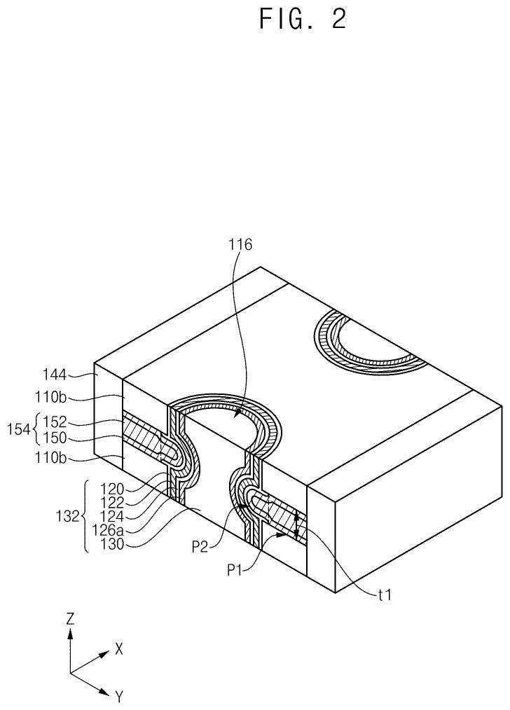

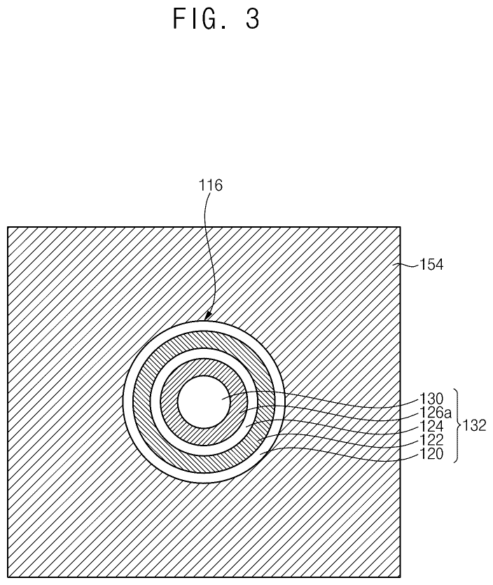

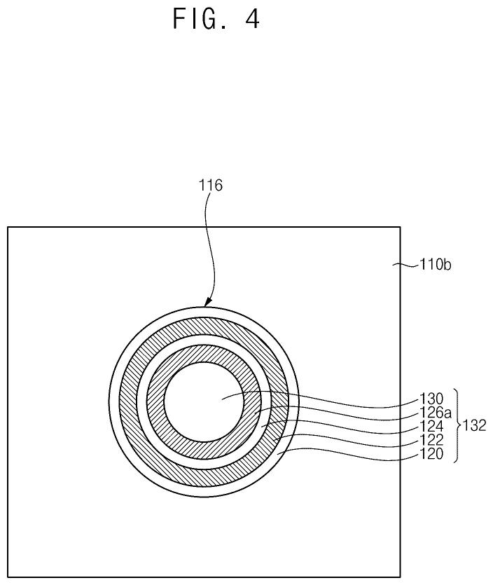

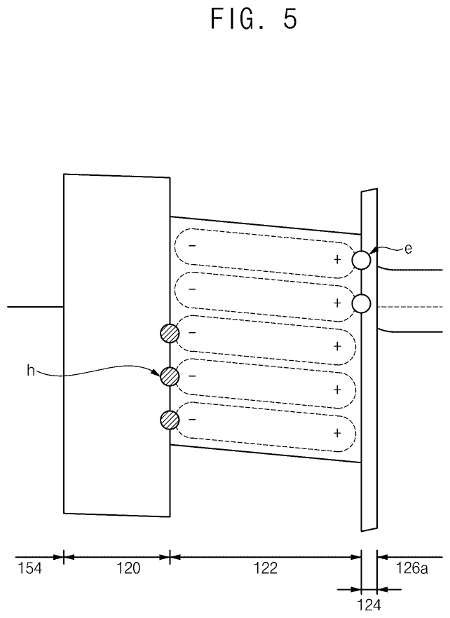

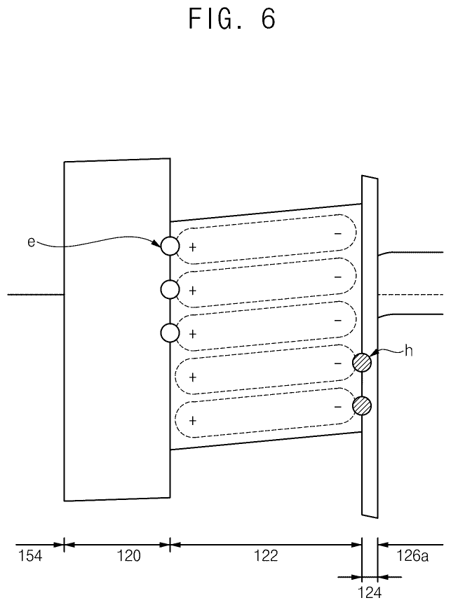

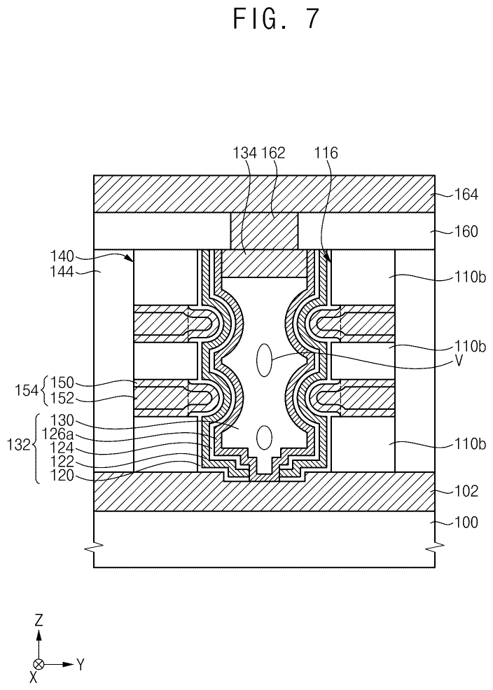

FIG. 1 is a vertical cross-sectional view illustrating a vertical semiconductor device according to example embodiments. FIG. 2 is a cutaway perspective view of a portion of a vertical semiconductor device according to example embodiments. FIGS. 3 and 4 are horizontal cross-sectional views (plan views) of portions of a vertical semiconductor device according to example embodiments. FIG. 5 illustrates an energy band of a memory cell of a programmed state in the vertical semiconductor device. FIG. 6 illustrates an energy band of a memory cell of an erased state in the vertical semiconductor device. FIG. 7 is a vertical cross-sectional view illustrating a vertical semiconductor device according to example embodiments.

FIG. 2 illustrates a portion corresponding to A in FIG. 1. FIG. 3 is a plan view showing a horizontal cut along line B-B′ of FIG. 1, and FIG. 4 is a plan view showing a horizontal cut along line C-C′ of FIG. 1.

Referring to FIGS. 1 to 4, a vertical semiconductor device may be formed on a substrate 100. The substrate 100 may include a semiconductor material such as silicon, germanium, silicon-germanium, or a group III-V compound such as GaP, GaAs, GaSb, etc. In some example embodiments, the substrate 100 may be a silicon-on-insulator SOI substrate or a germanium-on-insulator GOI substrate.

A source line 102 may be formed on the substrate 100. The source line 102 may include polysilicon, a metal, a conductive metal nitride, or a metal silicide doped with impurities. In some example embodiments, the source line may not be formed on the substrate, and the source line may be replaced with a source region doped with impurities in the substrate 100.

A stacked structure in which insulation layer patterns 110b and gate patterns 154 are alternately and repeatedly stacked may be disposed on the source line 102. Each gate pattern 154 disposed at corresponding one of different levels may extend lengthwise in the first direction X to serve as a word line of memory cells. One of the insulation layer patterns 110b may be disposed at an uppermost portion of the stacked structure.

A channel structure 132 may pass through the stacked structure, and the channel structure 132 may extend to the source line 102 in the vertical direction. The channel structure 132 may include a first insulation structure 130, a channel layer pattern 126a, a second interface insulation layer pattern 124, a ferroelectric layer pattern 122, and a first interface insulation layer pattern 120. An upper conductive pattern 134 may be disposed on the channel structure 132. The channel structure 132 may be disposed in a first hole 116 passing through the stacked structure. The channel structure 132 may have a pillar shape (e.g., a pillar shape with an interior filled). A bottom of the channel structure 132 may contact the source line 102.

The gate patterns 154 and the insulation layer patterns 110b may be exposed by/on a sidewall of the first hole 116. A sidewall of each of the insulation layer patterns 110b exposed by the first hole 116 may extend in a vertical direction or may have a constant slope close to the vertical direction. Each of the gate patterns 154 exposed by the first hole 116 may protrude toward an inside of the first hole 116 more than the sidewall of each of the insulation layer patterns 110b exposed by the first hole 116.

Accordingly, the sidewall of the first hole 116 may include vertical portions extending in a vertical direction and corresponding to (e.g., formed of) the sidewalls of the insulation layer patterns 110b and protruding portions corresponding to (e.g., formed of) the sidewalls of the gate patterns 154. In the sidewall of the first hole 116, the vertical portions and the protruding portions may be repeatedly and alternately arranged in the vertical direction. Each of the protruding portions of the first hole 116 may have a rounded shape, e.g., in a cross-sectional view.

As shown in FIGS. 1 to 4, an inner width (e.g., a width in a horizontal direction) of the first hole 116 corresponding to (e.g., horizontally overlapping) an exposed portion of the gate pattern 154 may be a relatively narrow. An inner width (e.g., a width in the horizontal direction) of the first hole 116 corresponding to (e.g., horizontally overlapping) an exposed portion of the insulation layer pattern 110b may be selectively expanded and relatively wide. Therefore, the inner width (e.g., the width in the horizontal direction) of the first hole 116 corresponding to (e.g., horizontally overlapping) the exposed portion of the gate pattern 154 may be less than the inner width (e.g., the width in the horizontal direction) of the first hole 116 corresponding to (e.g., horizontally overlapping) the exposed portion of the insulation layer pattern 110b.

The inner width (e.g., the width in a horizontal direction) of the first hole 116 corresponding to (e.g., horizontally overlapping) the exposed portion of the gate pattern 154 may gradually decrease and then gradually increase again in a direction moving upward or downward along the vertical direction.

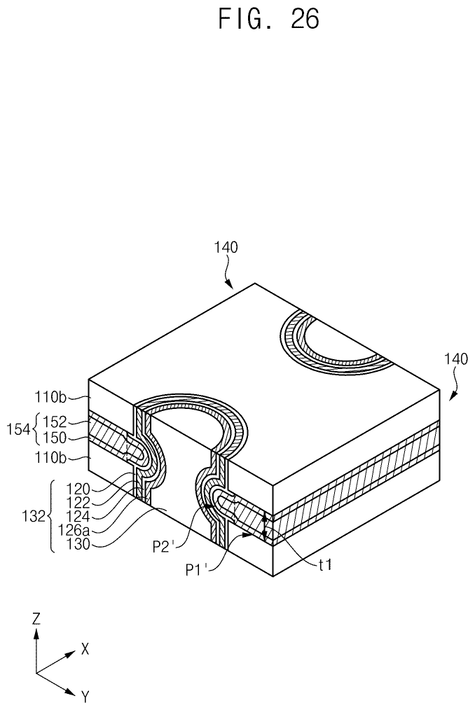

A portion of the gate pattern 154 interposed between (e.g., overlapping) the insulation layer patterns 110b in the vertical direction and having a first thickness t1 (e.g., shown in FIG. 26) in the vertical direction is referred to or defined as a first portion P1′ (e.g., shown in FIG. 26). A portion of the gate pattern 154 exposed by the first hole 116 and having a thickness less than the first thickness in the vertical direction is referred to or defined as a second portion P2′ (e.g., shown in FIG. 26). For example, a boundary between the first portion P1′ and the second portion P2′ of the gate pattern 154 may be defined by a vertical line connecting contact points between the gate pattern 154 and an upper and a lower insulation layer patterns 110b on a sidewall of the first hole 116 in a cross-sectional view. For example, the boundary between the first portion P1′ and the second portion P2′ may be a combination of a plurality of vertical lines connecting contact points between the gate pattern 154 and the upper and the lower insulation layer patterns 110b on the sidewall of the first hole 116 in respective cross-sectional views. The first thickness t1 may be the same as a thickness of a gap between the insulation layer patterns 110b in the vertical direction.

An upper surface and a lower surface of the first portion P1′ of the gate pattern 154 may contact an upper and a lower insulation layer patterns 110b, respectively. A surface of the second portion P2′ of the gate pattern 154 may not contact the insulation layer patterns 110b. An upper surface of the second portion P2′ of the gate pattern 154 may be lower than the upper surface of the first portion P1′ of the gate pattern 154. In addition, a lower surface of the second portion P2′ of the gate pattern 154 may be higher than the lower surface of the first portion P1′ of the gate pattern 154.

The surface of the second portion P2′ of the gate pattern 154 may include an upper portion, a sidewall portion, and a lower portion. At least an edge (e.g., a sidewall) of the second portion P2′ of the gate pattern 154 may be rounded. As the thickness of the second portion P2′ of the gate pattern 154 is less than the thickness of the first portion P1′ of the gate pattern 154, a radius of curved edge of the second portion P2′ of the gate pattern 154 may be smaller than a radius of curved edge of a gate pattern when the first and second portions of the gate pattern have the same thickness.

The sidewall of each of the insulation layer patterns 110b exposed by the first hole 116 may protrude toward the inside of the first hole 116 more than an interface/boundary between the first portion P1′ of the gate pattern 154 and the second portion P2′ of the gate pattern 154. For example, the interface/boundary between the first portion P1′ of the gate pattern 154 and the second portion P2′ of the gate pattern 154 may be positioned at an inner portion of the gap between the insulation layer patterns 110b in the vertical direction. For example, the boundary between the first portion P1′ of the gate pattern 154 and the second portion P2′ of the gate pattern 154 may vertically overlap the insulation layer patterns 110b. In example embodiments, a distance between the interface/boundary between the first portion P1′ of the gate pattern 154 and the second portion P2′ of the gate pattern 154 and the sidewall of the insulation layer pattern 110b may be similar to or less than a vertical distance between a bottom of the insulation layer pattern 110b and an upper surface of the second portion P2′ of the gate pattern 154 adjacent thereto. The second portion P2′ of the gate pattern 154 may laterally extend (e.g., in a horizontal direction) from behind the sidewall of the insulation layer pattern 110b toward a center of the first hole 116 more than the sidewall of the insulation layer pattern 110b, and thus a surface area of the second portion P2′ of the gate pattern 154 may be increased.

The first interface insulation layer pattern 120, the ferroelectric layer pattern 122, the second interface insulation layer pattern 124 and the channel layer pattern 126a may be sequentially stacked on surfaces of the insulation layer patterns 110b and the gate patterns 154 exposed by the first hole 116. The first insulation structure 130 may be disposed on the channel layer pattern 126a, and the first insulation structure 130 may fill the first hole 116.

The first interface insulation layer pattern 120 may be conformally formed on the surfaces of the second portions P2′ of the gate patterns 154 and the sidewalls/surfaces of the insulation layer patterns 110b. The first interface insulation layer pattern 120 may have a surface profile to which a surface profile of the second portion P2′ of the gate pattern 154 is transferred, so that a portion of the first interface insulation layer pattern 120 contacting the gate pattern 154 may protrude toward the inside of the first hole 116. The first interface insulation layer pattern 120 may include, e.g., silicon oxide or a metal oxide having a high dielectric constant.

The ferroelectric layer pattern 122 may be conformally formed on a surface of the first interface insulation layer pattern 120. Accordingly, the ferroelectric layer pattern 122 may have a surface profile to which the surface profile of the second portion P2′ of the gate pattern 154 is transferred, so that a portion of the ferroelectric layer pattern 122 facing or surrounding the gate pattern 154 may protrude toward the inside of the first hole 116.

In example embodiments, the ferroelectric layer pattern 122 may include a hafnium oxide layer, a zirconium oxide layer, or a hafnium zirconium oxide. The ferroelectric layer pattern 122 may have an orthorhombic phase. In example embodiments, the ferroelectric layer pattern 122 may further include a dopant, and the dopant may include, e.g., silicon (Si), zirconium (Zr), aluminum (Al), yttrium (Y), lanthanum (Layer), carbon (C), nitrogen (N), germanium (Ge), tin (Sn), strontium (Sr), lead (Pb), calcium (Ca), barium (Ba), titanium (Ti), zirconium (Zr), gadolinium (Gd), etc.

In some example embodiments, the ferroelectric layer pattern 122 may include a ferroelectric material having a perovskite structure. For example, the ferroelectric layer pattern 122 may include SrBi₂Ta₂O₉, (Bi,La)₄Ti₃O₁₂, or Pb, ZrTiO₃.

The second interface insulation layer pattern 124 may be conformally formed on a surface of the ferroelectric layer pattern 122. Therefore, the second interface insulation layer pattern 124 may have a surface profile to which the surface profile of the second portion P2′ of the gate pattern 154 is transferred, so that a portion of the second interface insulation layer pattern 124 facing or surrounding the gate pattern 154 may protrude toward the inside of the first hole 116.

The channel layer pattern 126a may be conformally formed on a surface of the second interface insulation layer pattern 124 and an upper surface of the source line 102. The channel layer pattern 126a may include a vertical portion and a horizontal portion. The horizontal portion of the channel layer pattern 126a may be connected to a bottom of the vertical portion of the channel layer pattern 126a and extend in a horizontal direction. The channel layer pattern 126a may have a surface profile to which the surface profile of the second portion P2′ of the gate pattern 154 is transferred, so that a portion of the channel layer pattern 126a facing or surrounding the gate pattern 154 may protrude toward the inside of the first hole 116.

A surface area of the protruding portion of the channel layer pattern 126a due to the surface profile of the second portion P2′ of the gate pattern 154 being transferred may be greater than a surface area of the second portion P2′ of the gate pattern 154. The channel layer pattern 126a may surround the second portion P2′ of the gate pattern 154. For example, the channel layer pattern 126a may surround the upper portion (e.g., an upper surface), the sidewall portion (e.g., a side surface), and the lower portion (e.g., a lower surface) of the second portion P2′ of the gate pattern 154. Accordingly, the channel layer pattern 126a may have a partial channel around structure (hereinafter, partial CA structure) in which the channel layer pattern 126a surrounds a portion (i.e., the second portion) of the gate pattern 154.

The channel layer pattern 126a may include, e.g., polysilicon, an oxide semiconductor, or a two-dimensional material. The oxide semiconductor may include, e.g., InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO or a combination thereof. The two-dimensional material may include, e.g., MoS₂, MoSe₂ or WS₂. A lower portion of the channel layer pattern 126a may be electrically connected to or contact the source line 102. In example embodiments, the channel layer pattern 126a may have a cylindrical shape or a cup shape. In some example embodiments, the channel layer pattern 126a may have a cylindrical shape with an open bottom.

As described above, the first interface insulation layer pattern 120, the ferroelectric layer pattern 122, the second interface insulation layer pattern 124, and the channel layer pattern 126a may be sequentially stacked on the sidewalls of the insulation layer patterns 110b and surfaces of the second portions P2′ of the gate patterns 154, along the surface profiles of the sidewalls of the insulation layer patterns 110b and the second portions P2′ of the gate pattern 154.

In addition, a structure including the first interface insulation layer pattern 120, the ferroelectric layer pattern 122, the second interface insulation layer pattern 124 and the channel layer pattern 126a stacked on the second portion P2′ of the gate pattern 154 may protrude in a lateral direction toward a center of the first hole 116 more than a structure of the first interface insulation layer pattern 120, the ferroelectric layer pattern 122, the second interface insulation layer pattern 124 and the channel layer pattern 126a stacked on the sidewall of the insulation layer pattern 110b.

Since the first insulation structure 130 is disposed on the channel layer pattern 126a to fill the first hole 116, a surface profile of the first insulation structure 130 may be the same or substantially the same as the surface profile of the channel layer pattern 126a. The first insulation structure 130 may have a pillar shape. A sidewall of the first insulation structure 130 may not have a constant slope or a vertical surface.

A portion of the first insulation structure 130 having a parallel surface with and/or facing the insulation layer pattern 110b may have a first width, e.g., in a horizontal direction (e.g., the second direction Y), and a portion of the first insulation structure 130 facing and/or horizontally overlapping the gate pattern 154 may have a second width, e.g., in the horizontal direction, less than the first width. The second width of the first insulation structure 130 may gradually decrease and then gradually increase again in a direction moving upward or downward along the vertical direction. The sidewall of the first insulation structure 130 facing and/or horizontally overlapping the gate pattern 154 may have a concave shape. The sidewall of the first insulation structure 130 not facing and/or not horizontally overlapping the gate pattern 154 may have a protruding shape, and may extend in a vertical direction or may have a slope extending in a direction close to the vertical direction. The first insulation structure 130 may include an oxide, e.g., silicon oxide.

In example embodiments, as shown in FIG. 1, the first insulation structure 130 may not include a void therein. In some example embodiments, as shown in FIG. 7, the first insulation structure 130 may include a void V therein. Due to the protruding portions of the sidewall of the first hole 116, the void may be included in the first insulation structure 130 facing and/or horizontally overlapping a central portion of each of the insulation layer patterns 110b.

The channel layer pattern 126a, the second interface insulation layer pattern 124, the ferroelectric layer pattern 122 and the first interface insulation layer pattern 120 may be sequentially stacked on an outer sidewall of the first insulation structure 130.

As described above, the channel layer pattern 126a may have the partial CA structure surrounding a portion of the gate pattern 154. The surface area of the second portion P2′ of the gate pattern 154 exposed by the first hole 116 may be increased by protruding the second portion P2′ of the gate pattern 154 from a side surface of the first hole 116. In addition, the surface area of the portion of the channel layer pattern 126a facing/surrounding the gate pattern 154 may be greater than the surface area of the second portion P2′ of the gate pattern 154. Therefore, a concentration of electric fields at the channel layer pattern 126a may be decreased. For example, in the partial CA structure in which the channel layer pattern 126a partially surrounds the gate pattern 154, the electric fields generated from the gate pattern 154 may be less concentrated at the channel layer pattern 126a, as compared to a GAA (gate all around structure) in which the gate pattern 154 completely surrounds (e.g., all four sides) the channel layer pattern 126a. Accordingly, the number of charges injected from the channel layer pattern 126a into the ferroelectric layer pattern 122 may be decreased. In addition, the number of charges injected from the gate pattern 154 into the ferroelectric layer pattern 122 may be increased.

When the number of charge injected from the channel layer pattern 126a into the ferroelectric layer pattern 122 is decreased and the number of charge injected from the gate pattern 154 into the ferroelectric layer pattern 122 is increased, a difference between the threshold voltage in the programming state of the memory cell and the threshold voltage in the erased state of the memory cell may be increased. Accordingly, a memory window in the memory cell may be increased, so that operating characteristics of the memory cell may be improved.

A second insulation structure 144 may be disposed on both sides of the stacked structure. In example embodiments, a bottom of the second insulation structure 144 may contact the source line 102. A plurality of stacked structures may be spaced apart from each other, and a first trench 140 may be disposed between the stacked structures. The second insulation structure 144 may fill the first trench 140. The second insulation structure 144 may extend, e.g., lengthwise, in the first direction X.

An upper insulating interlayer 160 may be disposed on the stacked structure, the channel structure 132, the second insulation structure 144, and the upper conductive pattern 134.

A bit line contact 162 may pass through the upper insulating interlayer 160, and may contact the upper conductive pattern 134.

A bit line 164 may be disposed on the upper insulating interlayer 160 and the bit line contact 162. The bit line 164 may extend lengthwise in the second direction Y. The bit line 164 may be electrically connected to the channel layer pattern 126a.

As described above, a unit memory cell of the vertical semiconductor device may include the channel layer pattern 126a, the second interface insulation layer pattern 124, the ferroelectric layer pattern 122, the first interface insulation layer pattern 120 and the gate pattern 154 laterally stacked on the first insulation structure 130. A portion of the gate pattern 154 may protrude toward the inside of the first hole 116, and the channel layer pattern 126a may surround the protruding portion of the gate pattern 154. Since the unit memory cell has the partial CA structure, the memory window of the unit memory cell may be increased. Accordingly, the vertical semiconductor device may have excellent operating characteristics.

The unit memory cell may be operated by changing a dipole field of the ferroelectric layer pattern 122.

Data may be written in the unit memory cell by changing the threshold voltage of the unit memory cell according to the dipole field of the ferroelectric layer pattern 122. In addition, data may be read from the unit memory cell by distinguishing drain currents according to voltages applied to the gate pattern 154 of the unit memory cell. Data stored in the unit memory cell may be determined according to a dipole direction in the ferroelectric layer pattern 122.

FIG. 5 is an energy band in an equilibrium state after performing a programming operation, and FIG. 6 is an energy band in an equilibrium state after performing an erasing operation.

Referring to FIG. 5, in a programming state, the ferroelectric layer pattern 122 may have a first dipole field in which a portion of the ferroelectric layer pattern 122 facing the channel layer pattern 126a has positive charges. In addition, electrons e may be injected from the channel layer pattern 126a to a surface of the ferroelectric layer pattern 122 adjacent to the channel layer pattern 126a. Holes may be injected from the gate pattern 154 to a surface of the ferroelectric layer pattern 122 adjacent to the gate pattern 154. Since the memory cell has the partial CA structure, the electrons injected into the surface of the ferroelectric layer pattern 122 due to or from the channel layer pattern 126a may be decreased. In addition, holes h injected into the surface of the ferroelectric layer pattern 122 due to or from the gate pattern 154 may be increased. Accordingly, a threshold voltage of the memory cell in the programming state may be decreased.

Referring to FIG. 6, in the erase state, the ferroelectric layer pattern 122 may have a second dipole field in which a portion of the ferroelectric layer pattern 122 facing the channel layer pattern 126a has negative charges. In addition, holes h may be injected from the channel layer pattern 126a into the surface of the ferroelectric layer pattern 122 adjacent to the channel layer pattern 126a. Electrons e may be injected from the gate pattern 154 into the surface of the ferroelectric layer pattern 122 adjacent to the gate pattern 154. Since the memory cell has the partial CA structure, holes h injected into the surface of the ferroelectric layer pattern 122 due to or from the channel layer pattern 126a may be decreased. In addition, electrons e injected into the surface of the ferroelectric layer pattern 122 due to or from the gate pattern 154a may be increased. Accordingly, a threshold voltage of the memory cell in the erase state may be increased.

Therefore, each of the unit memory cells having the partial CA structure may have an increased memory window and excellent operating characteristics.

The unit memory cell may be modified to have a slightly different stacked structure, which is explained below.

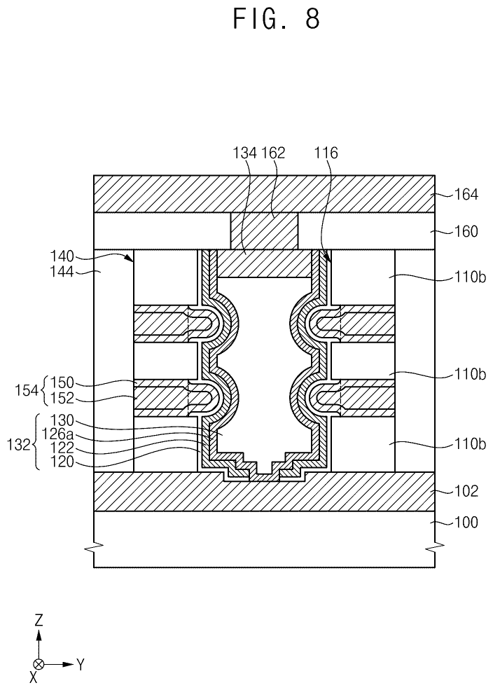

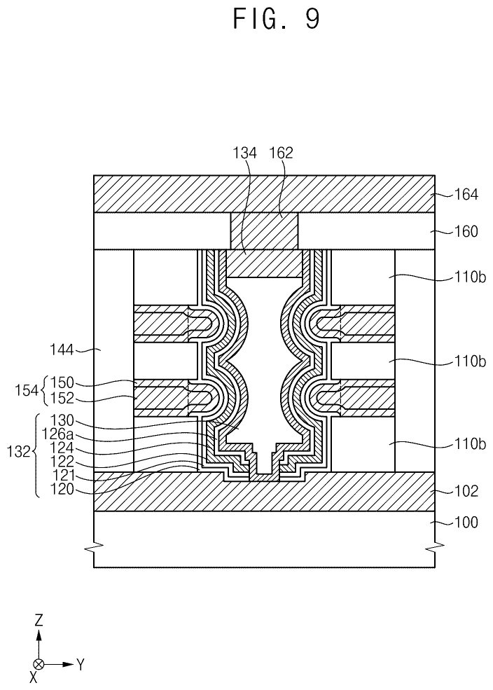

FIG. 8 is a vertical cross-sectional view illustrating a vertical semiconductor device according to example embodiments. FIG. 9 is a vertical cross-sectional view illustrating a vertical semiconductor device according to example embodiments.

Referring to FIG. 8, unit memory cell in the vertical semiconductor device may include the channel layer pattern 126a, the ferroelectric layer pattern 122, the first interface insulation layer pattern 120, and the gate pattern 154 laterally stacked on the first insulation structure 130. For example, as shown in FIG. 8, the second interface insulation layer pattern may not be included in the unit memory cell.

Referring to FIG. 9, unit memory cell in the vertical semiconductor device may include the channel layer pattern 126a, the second interface insulation layer pattern 124, the ferroelectric layer pattern 122, a trap silicon nitride layer 121, the first interface insulation layer pattern 120, and the gate pattern 154 laterally stacked on the first insulation structure 130. For example, as shown in FIG. 9, the unit memory cell may further include the trap silicon nitride layer 121 between the ferroelectric layer pattern 122 and the first interface insulation layer pattern 120.

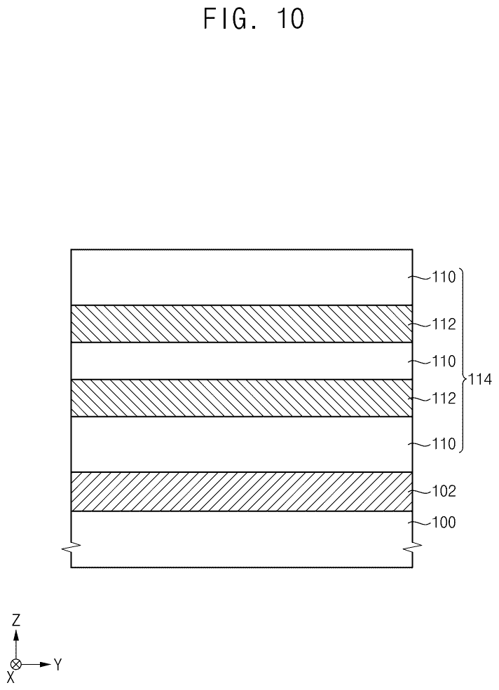

FIGS. 10 to 28 are cross-sectional views and perspective views illustrating a method of manufacturing a vertical semiconductor device according to example embodiments.

Referring to FIG. 10, a source line 102 may be formed on a substrate 100. The source line 102 may be formed by forming a first conductive layer and patterning the first conductive layer. The first conductive layer may be formed by, e.g., chemical vapor deposition or atomic layer deposition.

In example embodiments, lower circuit patterns for constituting peripheral circuits may be further formed on the substrate 100, and then a lower insulating interlayer may be further formed to cover the lower circuit patterns.

Insulation layers 110 and sacrificial layers 112 may be alternately and repeatedly formed on the source line 102 to form a mold structure 114. The sacrificial layers 112 may include an insulation material having a high etching selectivity with respect to the insulation layers 110. In example embodiments, the insulation layers 110 may include silicon oxide, and the sacrificial layers 112 may include silicon nitride. The number of each of the insulation layers 110 and the sacrificial layers 112 included in the mold structure 114 may not be limited. A memory cell may be subsequently formed at positions of each of the sacrificial layers 112 stacked in the vertical direction Z.

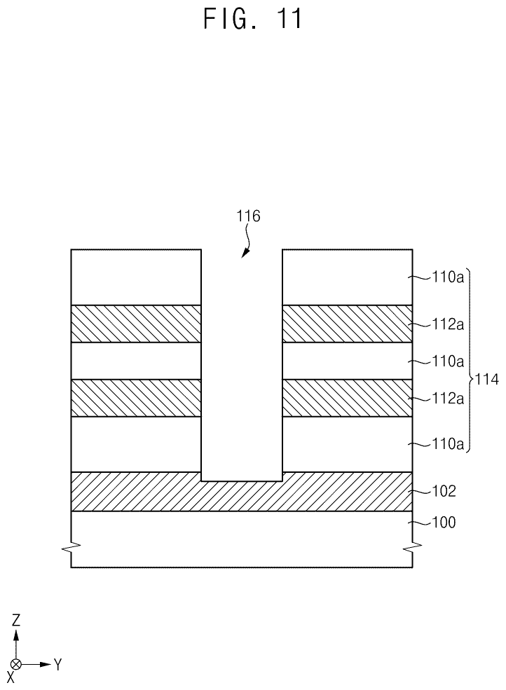

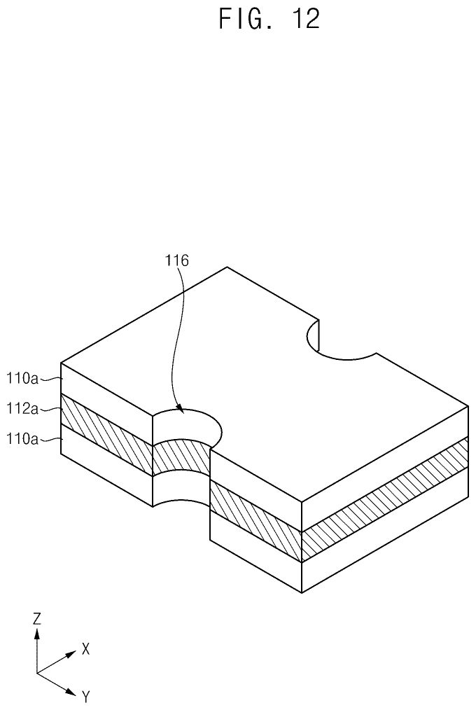

Referring to FIGS. 11 and 12, a portion of the mold structure 114 in which the insulation layers 110 and the sacrificial layers 112 are stacked may be anisotropically etched to form a first hole 116 passing through the mold structure 114 and exposing an upper portion of the source line 102. In order to avoid complexity of the drawing, only one first hole 116 is illustrated in the drawings but the number and the structure of first holes are not limited thereto. In example embodiments, a plurality of first holes 116 may be arranged in the mold structure 114. In example embodiments, the first holes 116 may be regularly arranged in the first direction X and the second direction Y. As the first holes 116 are formed in the mold structure 114, the insulation layers 110 and the sacrificial layers 112 may be transformed to preliminary insulation layer patterns 110a and preliminary sacrificial layer patterns 112a, respectively.

Sidewalls of the preliminary insulation layer patterns 110a and the preliminary sacrificial layer patterns 112a may be exposed by the first hole 116. For example, side surfaces of the preliminary insulation layer patterns 110a and the preliminary sacrificial layer patterns 112a may be exposed on a sidewall of the first hole 116.

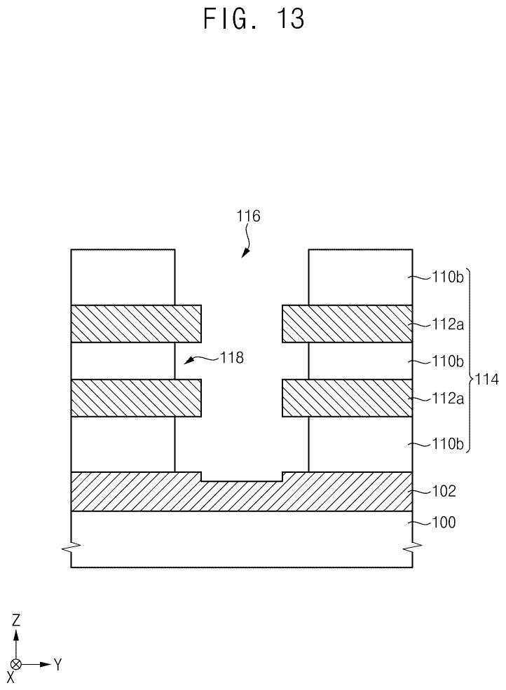

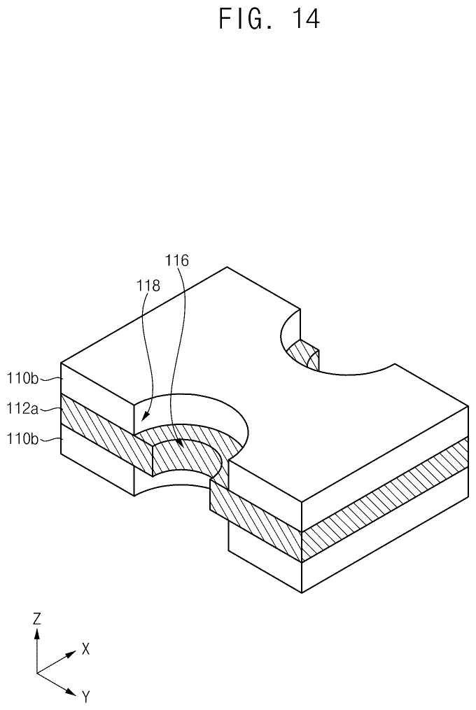

Referring to FIGS. 13 and 14, the preliminary insulation layer patterns 110a exposed by/on a sidewall of the first hole 116 may be removed laterally by a predetermined thickness to form the insulation layer patterns 110b. The removing process may include an isotropic etching process, e.g., a wet etching process.

The removing process may use an etchant having a high etching selectivity with respect to the preliminary sacrificial layer pattern 112a. For example, when the preliminary insulation layer pattern 110a includes silicon oxide and the preliminary sacrificial layer pattern 112a includes silicon nitride, the preliminary insulation layer pattern 110a may be removed by the predetermined thickness using the etchant including hydrofluoric acid.

A portion of the first hole 116 exposing the sacrificial layer pattern 112b may have a relatively narrow width, e.g., in a horizontal direction (e.g., the second direction Y). A width of a portion of the first hole 116 exposing the insulation layer pattern 110b may be selectively expanded.

In addition, within the first hole 116, the preliminary sacrificial layer patterns 112a may protrude toward an inside (e.g., toward a central region) of the first hole 116 more than the insulation layer patterns 110b. Therefore, a recessed portion 118 may be formed at the portion of the first hole exposing the insulation layer pattern 110b. For example, in the first hole, sidewalls of the insulation layer patterns 110b may be recessed from sidewalls of the preliminary sacrificial layer patterns 112a.

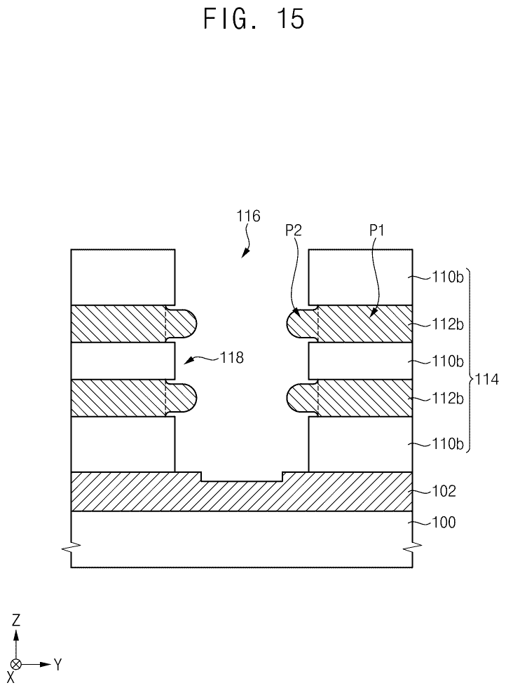

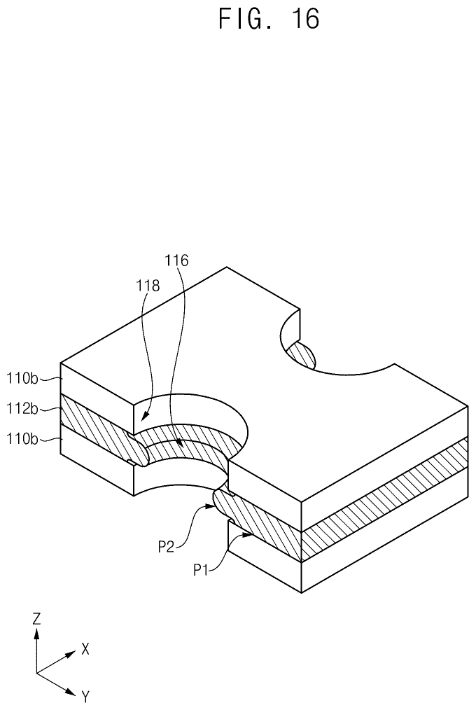

Referring to FIGS. 15 and 16, the preliminary sacrificial layer pattern 112a protruding from the sidewall of the first hole 116 may be isotropically etched by a predetermined thickness to form a sacrificial layer pattern 112b. The isotropic etching process may include, e.g., a wet etching process.

A portion of the sacrificial layer pattern 112b interposed between (e.g., vertically overlapping) the insulation layer patterns 110b and not exposed by the first hole 116 may be referred to or defined as a first portion P1, and a portion of the sacrificial layer pattern 112b exposed by the first hole 116 may be referred to or defined as a second portion P2. For example, a boundary between the first portion Pl and the second portion P2 of the sacrificial layer pattern 112b may be defined by a vertical line connecting contact points between the sacrificial layer pattern 112b and an upper and a lower insulation layer patterns 110b on a sidewall of the first hole 116 in a cross-sectional view. For example, the boundary between the first portion Pl and the second portion P2 may be a combination of a plurality of vertical lines connecting contact points between the sacrificial layer pattern 112b and the upper and the lower insulation layer patterns 110b on the sidewall of the first hole 116 in respective cross-sectional views.

As the preliminary sacrificial layer pattern 112a is partially etched by the isotropic etching to form the second portion P2 of the sacrificial layer pattern 112b, a thickness of the second portion P2 of the sacrificial layer pattern 112b, e.g., in a vertical direction, may be less than a thickness of the first portion P1 of the sacrificial layer pattern 112b, e.g., in the vertical direction.

An upper surface of the second portion P2 of the sacrificial layer pattern 112b may be lower than an upper surface of the first portion of the sacrificial layer pattern 112b. In addition, a lower surface of the second portion P2 of the sacrificial layer pattern 112b may be higher than a lower surface of the first portion of the sacrificial layer pattern 112b.

In addition, as the second portion P2 of the sacrificial layer pattern 112b is formed by the isotropic etching, at least an edge of the second portion P2 of the sacrificial layer pattern 112b may be rounded. Since the second portion P2 of the sacrificial layer pattern 112b has the thickness less than the thickness of the first portion P1 of the sacrificial layer pattern 112b, a radius of curvature of the second portion P2 of the sacrificial layer pattern 112b may be smaller than a radius of curvature of the edge of a gate pattern when the first and second portions have the same thickness.

A sidewall of the insulation layer pattern 110b exposed by the first hole 116 may protrude toward the inside of the first hole 116 more than the interface/boundary between the first portion P1 of the sacrificial layer pattern 112b and the second portion P2 of the sacrificial layer pattern 112b. For example, the interface/boundary between the first portion P1 of the sacrificial layer pattern 112b and the second portion P2 of the sacrificial layer pattern 112b may be disposed in a gap between the insulation layer patterns 110b in the vertical direction. For example, a horizontal distance between the interface/boundary between the first portion P1 of the sacrificial layer pattern 112b and the second portion P2 of the sacrificial layer pattern 112b and a side surface of the insulation layer pattern 110b exposed by the first hole 116 may be similar to or smaller than a vertical distance between an upper surface of the insulation layer pattern 110b and the second portion P2 of the sacrificial layer pattern 112b adjacent thereto. Since the second portion P2 of the sacrificial layer pattern 112b has a shape that laterally protrudes from behind the sidewall of the insulation layer pattern 110b toward a center of the first hole 116 more than the sidewall of the insulation layer pattern 110b, a surface area of the second portion P2 of the sacrificial layer pattern 112b may be increased.

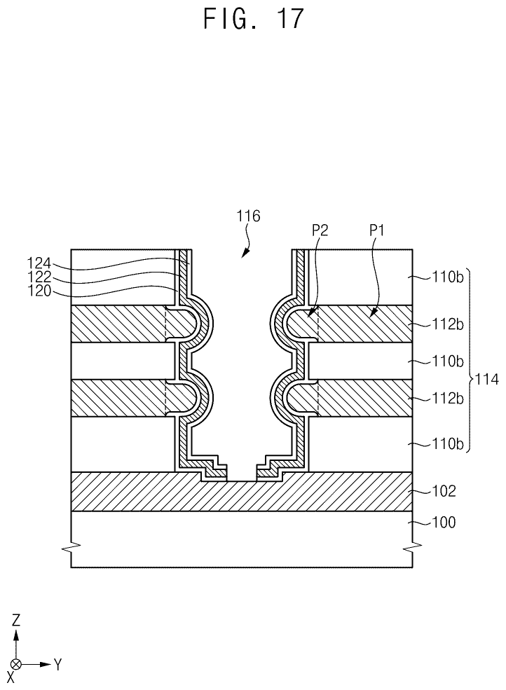

Referring to FIG. 17, a first interface insulation layer may be conformally formed on the sidewall and bottom of the first hole 116 and an upper surface of the mold structure 114.

A ferroelectric layer may be conformally formed on the surface of the first interface insulation layer along a surface profile of the sidewall and bottom of the first hole 116. A second interface insulation layer may be formed on the ferroelectric layer.

The first interface insulation layer, the ferroelectric layer, and the second interface insulation layer may be anisotropically etched to form a first interface insulation layer pattern 120, a ferroelectric layer pattern 122, and a second interface insulation layer pattern 124 sequentially stacked on the sidewall of the first hole 116. For example, the first interface insulation layer, the ferroelectric layer, and the second interface insulation layer on the bottom of the first hole 116 and the upper surface of the mold structure 114 may be selectively removed by the anisotropic etching process. Accordingly, the source line 102 may be exposed by/on the bottom of the first hole 116.

The first interface insulation layer pattern 120, the ferroelectric layer pattern 122, and the second interface insulation layer pattern 124 may be formed along surface profiles of the sidewall of the first hole 116 including side surfaces of the insulation layer pattern 110b and the second portion P2 of the sacrificial layer pattern 112b exposed by the first hole 116.

Therefore, the first interface insulation layer pattern 120, the ferroelectric layer pattern 122, and the second interface insulation layer pattern 124 may surround the surface of the second portion P2 of the sacrificial layer pattern 112b. For example, the first interface insulation layer pattern 120, the ferroelectric layer pattern 122, and the second interface insulation layer pattern 124 may surround/contact an upper portion (e.g., an upper surface), a sidewall (e.g., a side surface), and a lower portion (e.g., a lower surface) of the second portion P2 of the sacrificial layer pattern 112b.

The first interface insulation layer pattern 120, the ferroelectric layer pattern 122, and the second interface insulation layer pattern 124 may have surface profiles to which the surface profile of the second portion P2′ of the gate pattern 154 is transferred, so that portions of first interface insulation layer pattern 120, the ferroelectric layer pattern 122, and the second interface insulation layer pattern 124 facing or surrounding the gate pattern 154 may protrude toward the inside of the first hole 116.

In example embodiments, an area of a first surface of the first interface insulation layer pattern 120 contacting the second portion P2 of the sacrificial layer pattern 112b may be smaller than an area of a second surface of the first interface insulation layer pattern 120 opposite the first surface of the first interface insulation layer pattern 120. Similarly, an area of a first surface of the ferroelectric layer pattern 122 contacting the first interface insulation layer pattern 120 may be smaller than an area of a second surface of the ferroelectric layer pattern 122 opposite the first surface of the ferroelectric layer pattern 122. An area of a first surface of the second interface insulation layer pattern 124 contacting the ferroelectric layer pattern 122 may be smaller than an area of a second surface of the second interface insulation layer pattern 124 opposite the first surface of the second interface insulation layer pattern 124.

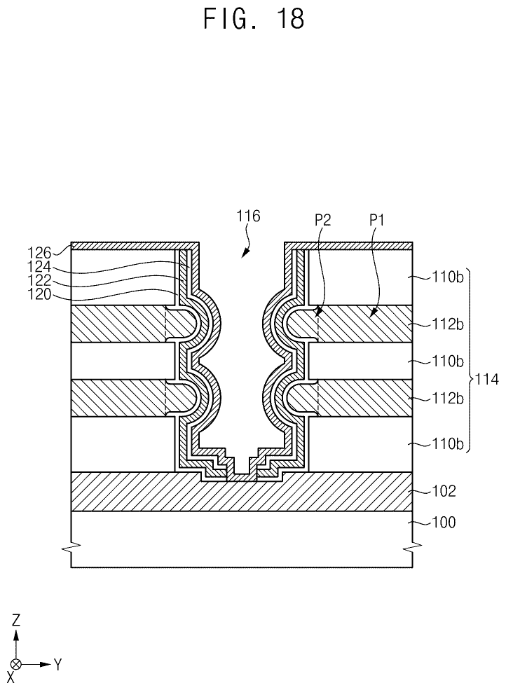

Referring to FIG. 18, a channel layer 126 may be conformally formed on a surface of the second interface insulation layer pattern 124, a bottom of the first hole 116, and an upper surface of the mold structure 114. Accordingly, the first interface insulation layer pattern 120, the ferroelectric layer pattern 122, the second interface insulation layer pattern 124, and the channel layer 126 may be sequentially stacked on the sidewall of the first hole 116.

The channel layer 126 may be formed to have a surface profile to which the surface profile of the second portion P2 of the sacrificial layer pattern 112b is transferred, so that a portion of the channel layer 126 facing or surrounding the second portion P2 of the sacrificial layer pattern 112b may protrude toward the inside of the first hole 116. For example, the portion of the channel layer 126 surrounding and/or horizontally overlapping the second portion P2 of the sacrificial layer pattern 112b may be convex to the first hole 116.

An area of a first surface of the channel layer 126 contacting the second interface insulation layer pattern 124 may be smaller than an area of a second surface of the channel layer 126 opposite the first surface of the channel layer 126.

The channel layer 126 may be formed to have the surface profile to which the surface profile of the second portion P2 of the sacrificial layer pattern 112b is transferred, so that a surface area of the portion of the channel layer facing or surrounding the second portion P2 of the sacrificial layer pattern 112b may be greater than a surface area of the second portion P2 of the sacrificial layer pattern 112b.

Since the channel layer 126 is formed along the profiles of an upper portion, a sidewall portion, and a lower portion of the second portion P2 of the sacrificial layer pattern 112b, the channel layer 126 may surround the upper portion, the sidewall portion, and the lower portion of the second portion P2 of the sacrificial layer pattern 112b.

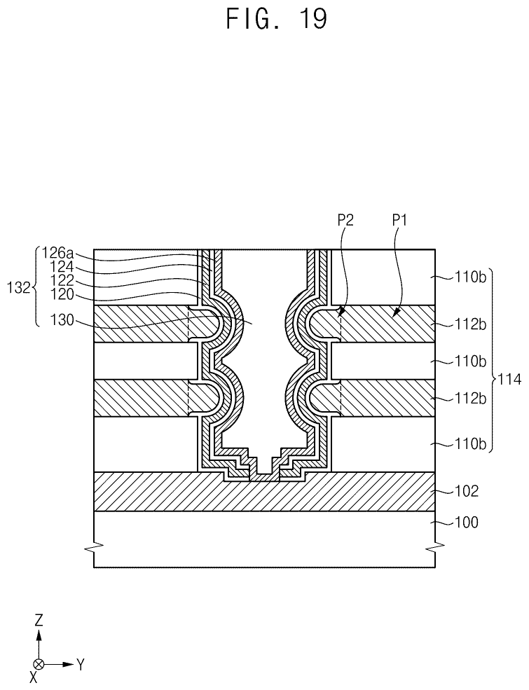

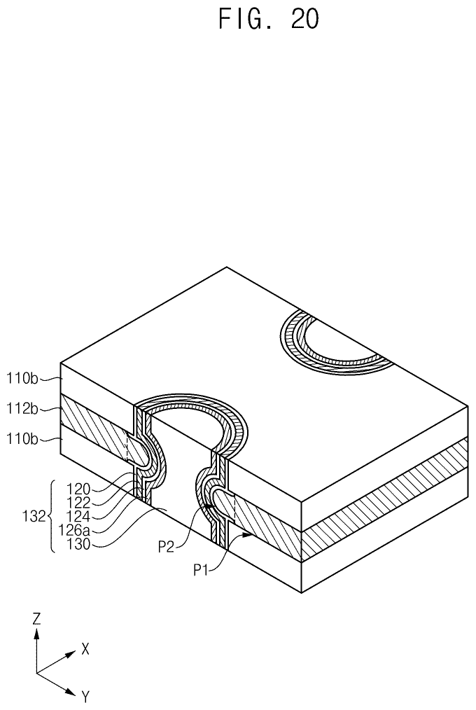

Referring to FIGS. 19 and 20, a filling insulation layer may be formed on the channel layer 126 to completely fill the first hole 116. Thereafter, the filling insulation layer and the channel layer 126 may be planarized until the upper surface of the mold structure 114 is exposed to form a first insulation structure 130 and a channel layer pattern 126a. The planarization process may include a chemical mechanical polishing process or an etch-back process. The first insulation structure 130 may fill the first hole 116. The first interface insulation layer pattern 120, the ferroelectric layer pattern 122, the second interface insulation layer pattern 124, and the channel layer pattern 126a may surround a sidewall of the first insulation structure 130. In addition, the first interface insulation layer pattern 120, the ferroelectric layer pattern 122, the second interface insulation layer pattern 124, and the channel layer pattern 126a may surround the second portion P2 of the sacrificial layer pattern 112b.

A stacked structure including the first insulation structure 130, the channel layer pattern 126a, the second interface insulation layer pattern 124, the ferroelectric layer pattern 122, and the first interface insulation layer pattern 120 may be referred to as a channel structure 132. The channel structure 132 may pass through the mold structure 114, and may extend to the source line 102 in the vertical direction Z. The channel layer pattern 126a may be electrically connected to and/or contact the source line 102. A portion of the channel structure 132 contacting the insulation layer pattern 110b may have a constant slope or a vertical surface, and a portion of the channel structure 132 contacting the second portion P2 of the sacrificial layer pattern 112b may protrude toward the inside of the first hole 116.

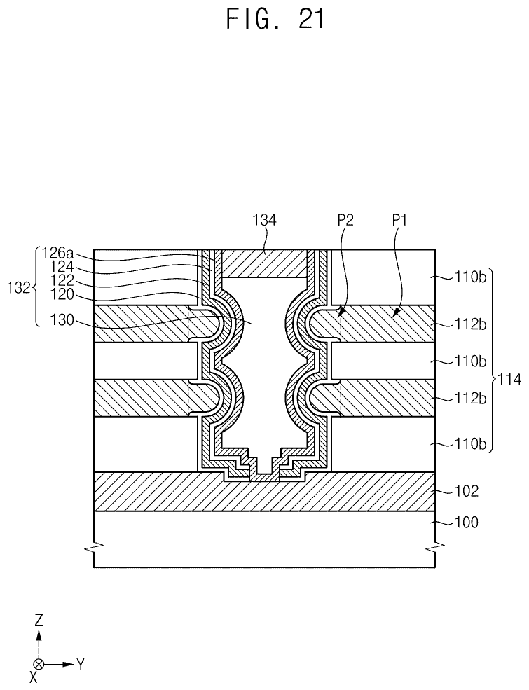

Referring to FIG. 21, an upper portion of the first insulation structure 130 may be partially removed to form an upper recess. The channel layer pattern 126a may be exposed by the sidewall of the upper recess. A conductive material may fill the upper recess to form an upper conductive pattern 134. The upper conductive pattern 134 may be electrically connected to and/or contact the channel layer pattern 126a. The upper conductive pattern 134 may serve as a pad pattern for electrically connecting to a bit line subsequently formed. In some example embodiments, processes for forming the upper conductive pattern 134 may be omitted, thereby omitting the upper conductive pattern 134.

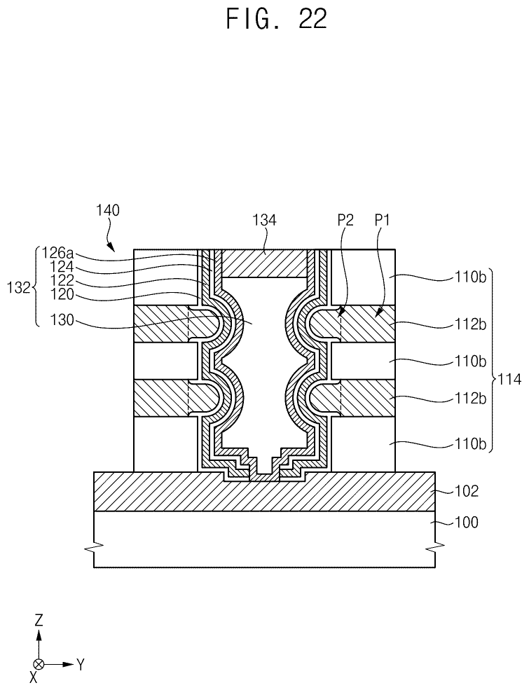

Referring to FIG. 22, first trenches 140 may be formed that pass through the mold structure 114 and extend in the vertical direction to at least the inside of a lowermost insulation layer pattern 110b. The first trench 140 may extend in the first direction X, and the first trench 140 may be spaced apart from the channel structure 132, e.g., in the second direction Y.

The insulation layer patterns 110b and the sacrificial layer patterns 112b may be exposed by/on the sidewall of the first trench 140.

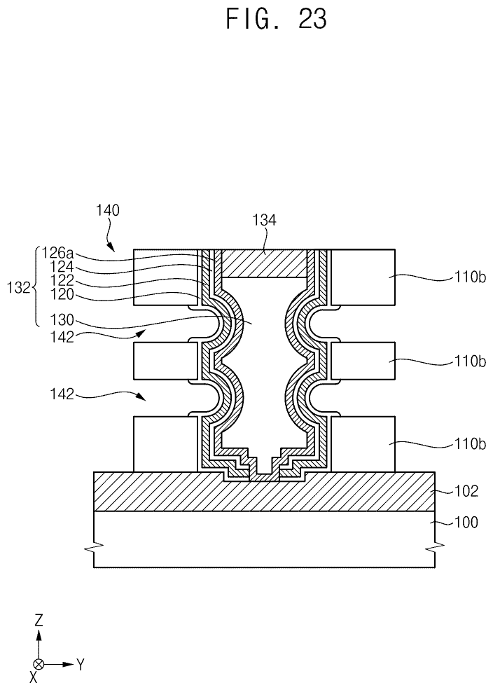

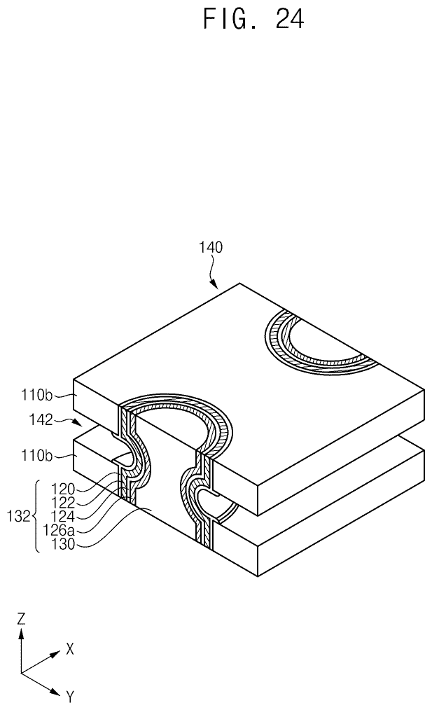

Referring to FIG. 23 and FIG. 24, the sacrificial layer patterns 112b exposed by/on the sidewall of the first trench 140 may be selectively removed. The process for selectively removing of the sacrificial layer patterns 112b may include an isotropic etching process. Accordingly, the insulation layer patterns 110b may remain on the sidewall of the channel structure 132 so as to protrude from a sidewall of the channel structure 132, e.g., toward the first trench 140. In addition, a gap 142 may be formed between the insulation layer patterns 110b in the vertical direction Z.

A portion of the channel structure 132 may be exposed by the gap 142 where the second portions P2 of the sacrificial layer patterns 112b are removed. An outer sidewall of the channel structure 132 (e.g., the first interface insulation layer pattern 120) may be exposed by the gap 142. A portion of the gap 142 where the channel structure 132 is exposed may extend in the second direction Y toward the first hole 116.

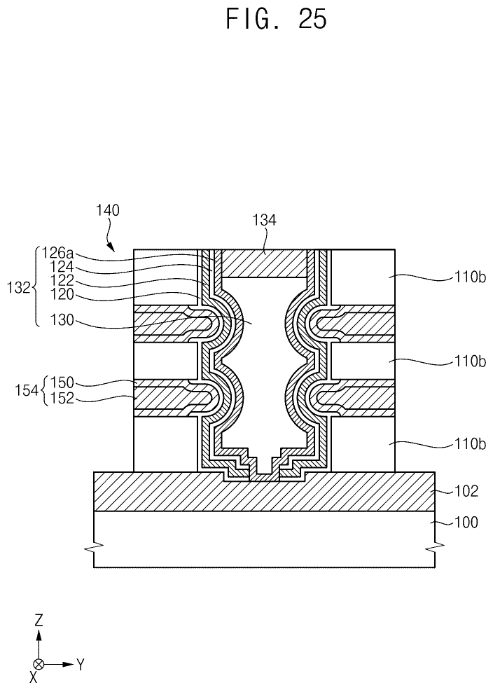

Referring to FIGS. 25 and 26, a conductive material may fill the gaps 142 to form a gate pattern 154 in each of the gaps 142. The gate pattern 154 may include, e.g., a metal. The gate pattern 154 may include a barrier metal pattern 150 and a metal pattern 152. In example embodiments, a barrier metal layer may be formed along a surface of the gap 142, a surface of the first trench 140, and an upper surface of an uppermost insulation layer pattern 110b. A metal layer may be formed on the barrier metal layer to fill the gap 142. Thereafter, the barrier metal layer and the metal layer disposed on the surface of the first trench 140 and the upper surface of the uppermost insulation layer pattern 110b may be removed so that the barrier metal layer and the metal layer may remain only in the gap 142. Accordingly, a gate pattern 154 may be formed in the gap 142. The gate pattern 154 may extend, e.g., lengthwise, in the first direction X, and the gate pattern 154 may serve as a word line. The removing process of the metal layer may include an isotropic etching process, e.g., a wet etching process.

By the processes described above, the sacrificial layer patterns 112b may be replaced with the gate patterns 154. Accordingly, the gate pattern 154 may have the same or substantially the same shape as the sacrificial layer pattern 112b. The gate pattern 154 may have a first portion P1′ interposed between the insulation layer patterns 110b in the vertical direction and having a first thickness t1, and a second portion P2′ contacting the channel structure 132. The first portion P1′ of the gate pattern 154 may have the same shape as the first portion P1 of the sacrificial layer pattern 112b, and the second portion P2′ of the gate pattern 154 may have the same shape as the second portion P2 of the sacrificial layer pattern 112b, e.g., when the first trench 140 is formed.

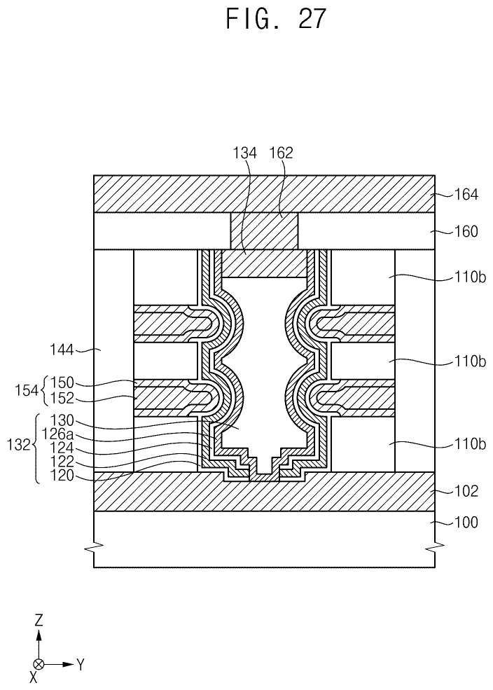

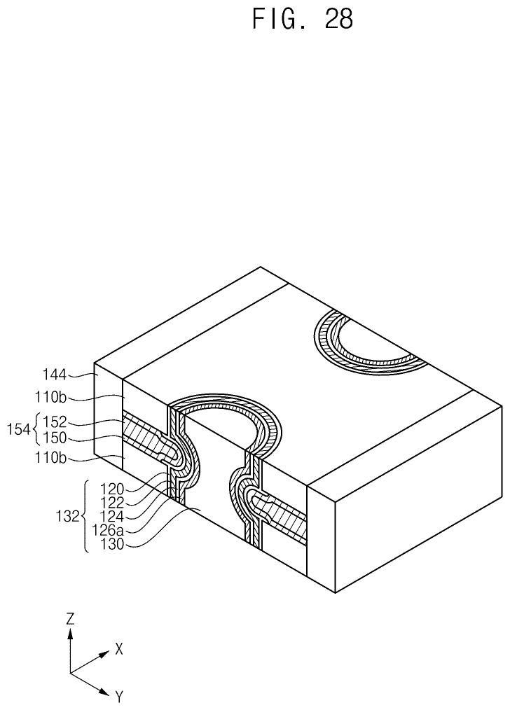

Referring to FIGS. 27 and 28, a second insulation structure 144 may be formed in the first trench 140. The second insulation structure 144 may include, e.g., silicon oxide or silicon nitride.

An upper insulating interlayer 160 may be formed on the second insulation structure 144, the insulation layer pattern 110b, the channel structure 132, and the upper conductive pattern 134. The upper insulating interlayer 160 may cover and/or vertically overlap the second insulation structure 144, the insulation layer pattern 110b, the channel structure 132, and the upper conductive pattern 134.

A bit line contact 162 may be formed through the upper insulating interlayer 160, and the bit line contact 162 may be electrically connected to and/or contact the upper conductive pattern 134. Thereafter, a bit line 164 contacting the bit line contact 162 may be formed on the upper insulating interlayer 160.

In some example embodiments, the processes for forming the bit line contact 162 may be omitted, thereby omitting the bit line contact 162. In this case, a portion of the upper insulating interlayer 160 may be etched to form an upper trench exposing the upper conductive pattern 134, and a bit line 164 contacting the upper conductive pattern 134 may be formed in the upper trench.

By the method described above, a vertical semiconductor device may be manufactured.

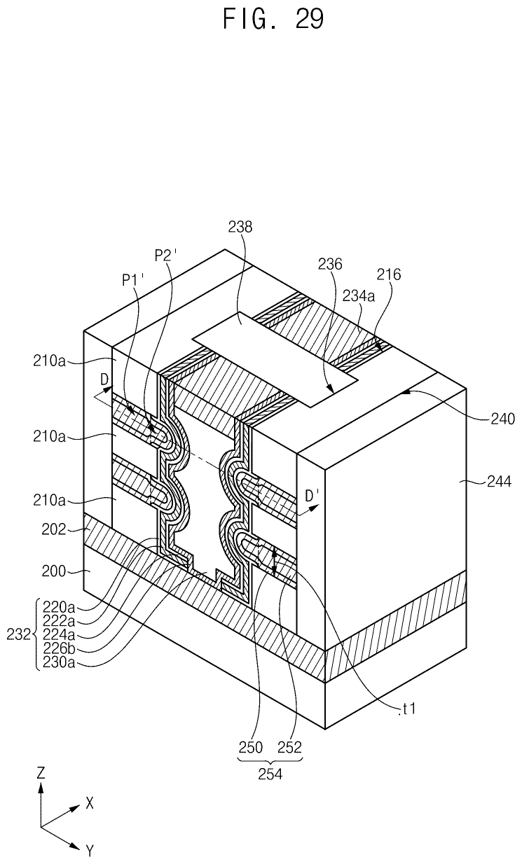

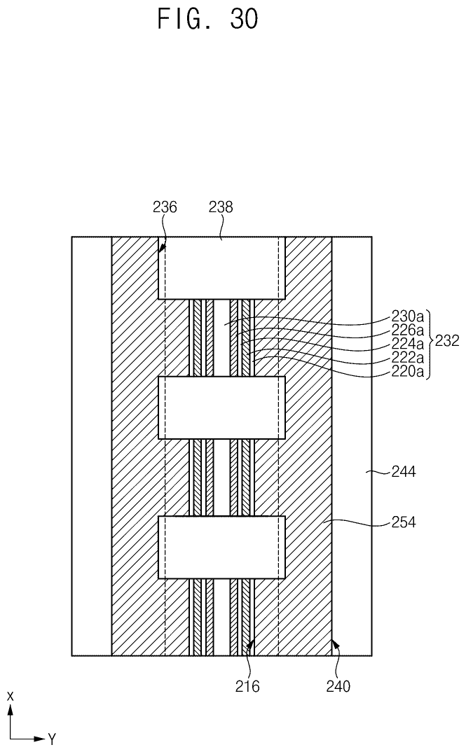

FIG. 29 is a perspective view illustrating a vertical semiconductor device according to example embodiments. FIG. 30 is a horizontal cross-sectional view (a plan view) of a portion of a vertical semiconductor device according to example embodiments.

FIG. 30 is a horizontal cross-sectional view (a plan view) taken from a horizontal plane along line D-D′ of FIG. 29.

Referring to FIGS. 29 and 30, a source line 202 may be formed on a substrate 200.

A stacked structure in which insulation layer patterns 210a and gate patterns 254 are alternately and repeatedly stacked may be disposed on the source line 202. Each of the gate patterns 254 may extend lengthwise in the first direction X, and each of the gate patterns 254 may serve as a word line of memory cells.

A first trench 216 and a second trench 240 extending in the first direction X and passing through the stacked structure may be arranged. The first and second trenches 216 and 240 may be alternately arranged in the second direction Y.

The gate patterns 254 and the insulation layer patterns 210a may be exposed by/on the sidewall of the first trench 216. The sidewalls of the insulation layer patterns 210a exposed by the first trench 216 may extend in a vertical direction or may have a constant slope close to the vertical direction. The gate patterns 254 exposed by the first trench 216 may protrude toward inside or a center of the first trench 216 more than a sidewall of the insulation layer pattern 210a exposed by the first trench 216.

A portion of a gate pattern 254 interposed between (e.g., overlapping) the insulation layer patterns 210a in the vertical direction and having a first thickness t1 in the vertical direction may be referred to as a first portion P1′. A portion of the gate pattern 254 exposed by the first trench 216 and having a thickness less than the first thickness t1 in the vertical direction is referred to as a second portion P2′. For example, a boundary between the first portion P1′ and the second portion P2′ of the gate pattern 254 may be defined by a vertical line connecting contact points between the gate pattern 254 and an upper and a lower insulation layer patterns 210a on a sidewall of the first trench 216. For example, the boundary between the first portion P1′ and the second portion P2′ may be a combination of a plurality of vertical lines connecting contact points between the gate pattern 254 and the upper and the lower insulation layer patterns 210a on the sidewall of the first trench 216 in respective cross-sectional views. The first thickness t1 may be the same as a thickness/distance of the gap between the insulation layer patterns 210a in the vertical direction.

An upper surface and a lower surface of the first portion P1′ of the gate pattern 254 may contact the insulation layer pattern 210a. A surface of the second portion P2′ of the gate pattern 254 may not contact the insulation layer pattern 210a.

An upper surface of the second portion P2′ of the gate pattern 254 may be lower than the upper surface of the first portion P1′ of the gate pattern 254. In addition, the lower surface of the second portion P2′ of the gate pattern 254 may be higher than the lower surface of the first portion P1′ of the gate pattern 254.

At least an edge of the second portion P2′ of the gate pattern 254 may be rounded.

The channel structure 232 extending to the upper portion/surface of the source line 202 from the uppermost insulation layer pattern 210a in the vertical direction Z and having a pillar shape may be provided in the first trench 216. A plurality of channel structures 232 may be spaced apart from each other in the first direction X in the first trench 216.

A plurality of first separation patterns 238 may be formed between the plurality of channel structures 232 inside the first trench 216. The first separation patterns 238 may include an insulation material.

A second separation pattern 244 may be provided in the second trench 240 to fill the second trench 240. The second separation pattern 244 may extend, e.g., lengthwise, in the first direction X. The second separation pattern 244 may include an insulation material.

The channel structure 232 may include a first insulation structure 230a, a channel layer pattern 226b, a second interface insulation layer pattern 224a, a ferroelectric layer pattern 222a, and a first interface insulation layer pattern 220a.

The first interface insulation layer pattern 220a, the ferroelectric layer pattern 222a, the second interface insulation layer pattern 224a, and the channel layer pattern 226b may be sequentially stacked on surfaces of the insulation layer patterns 210a and the gate patterns 254 exposed by the first trench 216. The first insulation structure 230a may be disposed on the channel layer pattern 226b.

The first insulation structure 230a may have a first sidewall and a second sidewall opposite each other in the second direction, and the channel layer pattern 226b, the second interface insulation layer pattern 224a, the ferroelectric layer pattern 222a, and the first interface insulation layer pattern 220a may be sequentially stacked on the first and second sidewalls of the first insulation structure 230a.

The first interface insulation layer pattern 220a may be conformally formed on a surface of the second portion P2′ of the gate pattern 254 and the sidewall of the insulation layer pattern 210a. Accordingly, the first interface insulation layer pattern 220a may have a surface profile to which the surface profile of the second portion P2 of the sacrificial layer pattern 112b is transferred. A portion of the first interface insulation layer pattern 220a contacting the gate pattern 254 may protrude toward the inside of the first trench 216.

The ferroelectric layer pattern 222a may be conformally formed on a surface of the first interface insulation layer pattern 220. Therefore, the ferroelectric layer pattern 222a may have a surface profile to which the surface profile of the second portion P2′ of the gate pattern 254 is transferred. A portion of the ferroelectric layer pattern 222a facing/surrounding the gate pattern 254 may protrude toward the inside of the first trench 216.

The second interface insulation layer pattern 224a may be conformally formed on a surface of the ferroelectric layer pattern 222a. Therefore, the second interface insulation layer pattern 224a may have a surface profile to which the surface profile of the second portion P2′ of the gate pattern 254 is transferred. The second interface insulation layer pattern 224a may protrude toward the inside of the first trench 216.

The channel layer pattern 226b may be conformally formed on a surface of the second interface insulation layer pattern 224a and an upper surface of the source line 202. The channel layer pattern 226b may have a vertical portion and a horizontal direction. The horizontal portion of the channel layer pattern 226b may be connected to a bottom of the vertical portion of the channel layer pattern 226b. The channel layer pattern 226b may have a U-shape including a first sidewall, a bottom, and a second sidewall facing the first sidewall, e.g., in a cross-sectional view. The channel layer pattern 226b may have a surface profile to which the surface profile of the second portion P2′ of the gate pattern 254 is transferred. A portion of the channel layer pattern 226b facing/surrounding the gate pattern 254 may protrude toward the inside of the first trench 216.

The first insulation structure 230a may be formed on the channel layer pattern 226b. The first insulation structure 230a may fill a space between the first trench 216 and the first separation pattern 238.

A sidewall of the first insulation structure 230a may not have a constant slope or a vertical surface. A portion of the first insulation structure 230a facing and/or horizontally overlapping the gate pattern 254 may have a relatively narrow width, e.g., in the second direction Y, and a portion of the first insulation structure 230a not facing the gate pattern 254 and/or horizontally overlapping the insulation layer patterns 210a may have a relatively wide width. A sidewall of the portion of the first insulation structure 230a facing and/or horizontally overlapping the gate pattern 254 may have a concave shape, and the sidewall of the portion of the first insulation structure 230a not facing the gate pattern 254 and/or horizontally overlapping the insulation layer patterns 210a may have a protruding shape. The first insulation structure 230a may include, e.g., silicon oxide.

The gate patterns 254 may extend lengthwise in the first direction X. Two gate patterns 254 may be disposed to face the first sidewall and the second sidewall of the channel layer pattern 226a, respectively. For example, one memory cell may be formed on the first sidewall of the channel layer pattern 226a, and another memory cell may be formed on the second sidewall of the channel layer pattern 226a. The gate patterns 254 may be spaced apart from each other in the vertical direction Z.

The gate pattern 254 may include a barrier metal pattern 250 and a metal pattern 252.

The gate pattern 254 may contact the first interface insulation layer pattern 220a included in the channel structure 232.

An upper conductive pattern 234a may be formed on the upper portion/surface of the first insulation structure 230a, and the upper conductive pattern 234a may contact the upper sidewall of the channel layer pattern 226b. The upper conductive pattern 234a may serve as a bit line pad.

An upper insulating interlayer may be on the stacked structure, the channel structure 232 and the first insulation structure 230a.

A bit line contact may pass through the upper insulating interlayer and may contact the upper conductive pattern 234a. A bit line may be on the upper insulating interlayer and the bit line contact.

As described above, the second interface insulation layer pattern 224a, the ferroelectric layer pattern 222a, the first interface insulation layer pattern 220a, and the gate pattern 254 may be stacked on each of the first sidewall and the second sidewall of the channel layer pattern 226b. The second interface insulation layer pattern 224a, the ferroelectric layer pattern 222a, the first interface insulation layer pattern 220a, and the gate pattern 254 stacked on each of the first sidewall and the second sidewall of the channel layer pattern 226b may not be connected to each other. Therefore, two memory cells may be formed on one channel layer pattern 226b at the same vertical level.

The channel layer pattern 226b may have a structure surrounding a portion of the gate pattern 254. Therefore, unit memory cell may have an increased memory window and may have excellent operating characteristics.

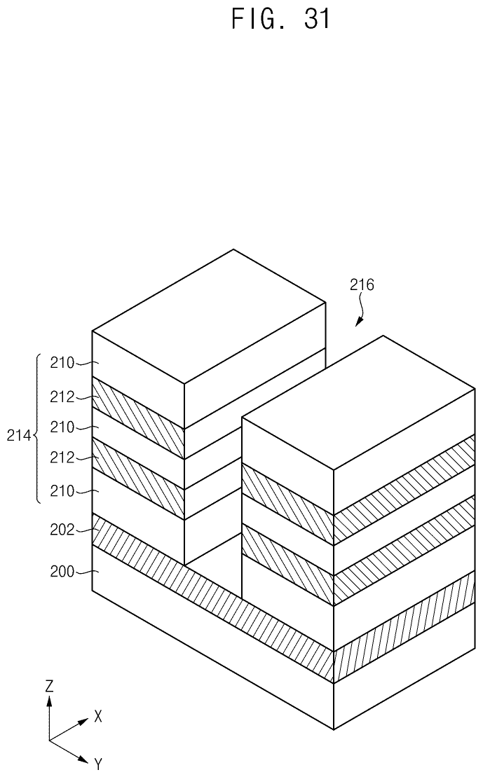

FIGS. 31 to 37 are perspective views illustrating a method of manufacturing a vertical semiconductor device according to example embodiments.

Referring to FIG. 31, first, the process described with reference to FIG. 10 may be performed to form a source line 202 and a mold structure 214 on a substrate 200.

Thereafter, the mold structure 214 in which the insulation layers and the sacrificial layers are alternately stacked may be anisotropically etched to form a first trench 216 passing through the mold structure 214 and exposing an upper portion/surface of the source line 202.

The first trench 216 may extend, e.g., lengthwise, in the first direction X. In order to avoid complexity of the drawing, only one first trench 216 is illustrated in FIG. 31 but the number of trenches 216 is not limited thereto. In example embodiments, a plurality of first trenches 216 may be provided in the mold structure 214. In example embodiments, the first trenches 216 may be regularly arranged in the first direction X and the second direction Y. The insulation layers and the sacrificial layers may be transformed as preliminary insulation layer patterns 210 and preliminary sacrificial layer patterns 212, respectively, by forming the first trench 216.

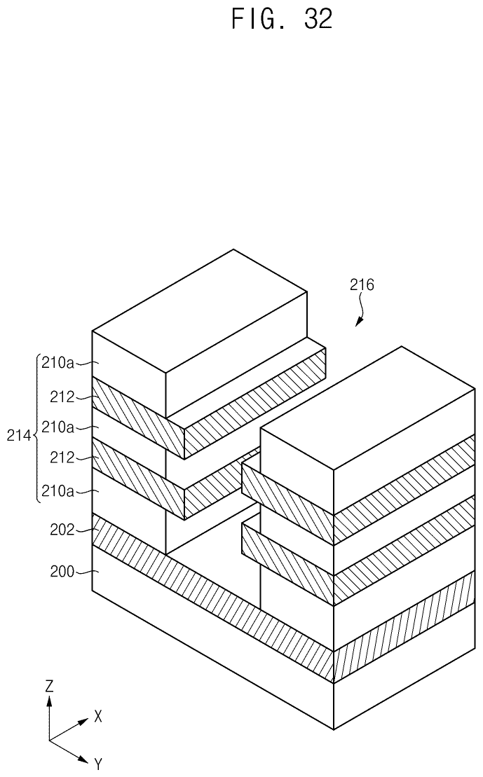

Referring to FIG. 32, the preliminary insulation layer patterns 210 exposed by/on the sidewall of the first trench 216 may be removed laterally by a predetermined thickness to form the insulation layer patterns 210a. The removing process may include an isotropic etching process, e.g., a wet etching process.

The processes described above may be the same or substantially the same as those described with reference to FIGS. 13 and 14 above.

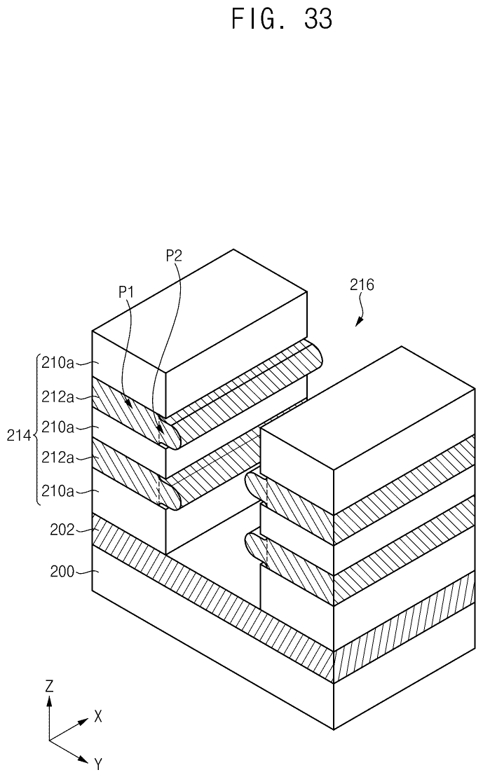

Referring to FIG. 33, the preliminary sacrificial layer patterns 212 protruding from the sidewall of the first trench 216 may be isotropically etched by a predetermined thickness to form the sacrificial layer patterns 212a. The isotropic etching process may include, e.g., a wet etching process.

A portion of the sacrificial layer pattern 212a interposed between the insulation layer patterns 210a and not exposed by the first trench 216 may be referred to as a first portion P1. A portion of the sacrificial layer pattern 212a exposed by the first trench 216 may be referred to as a second portion P2. For example, a boundary between the first portion P1 and the second portion P2 of the sacrificial layer pattern 212a may be defined by a vertical line connecting contact points between the sacrificial layer pattern 212a and an upper and a lower insulation layer patterns 210a on a sidewall of the first trench 216. For example, the boundary between the first portion P1 and the second portion P2 may be a combination of a plurality of vertical lines connecting contact points between the sacrificial layer pattern 212a and the upper and the lower insulation layer patterns 210a on the sidewall of the first trench 216 in respective cross-sectional views. The second portion P2 may extend, e.g., lengthwise, in the first direction.

The processes described above may be the same or substantially the same as those described with reference to FIGS. 15 and 16 above.

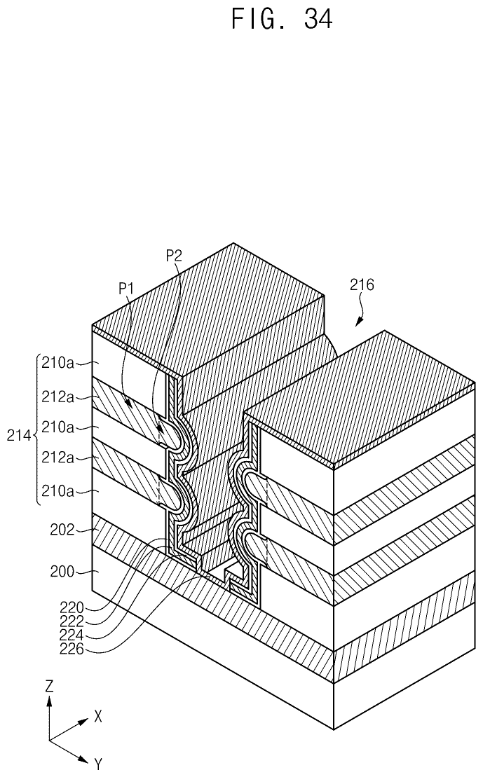

Referring to FIG. 34, a first interface insulation layer may be conformally formed on the sidewall and bottom of the first trench 216 and an upper surface of the mold structure 214.

A ferroelectric layer may be conformally formed on the surface of the first interface insulation layer along the profile of the sidewall and bottom of the first trench 216, and a second interface insulation layer may be formed on the ferroelectric layer.

The first interface insulation layer, the ferroelectric layer, and the second interface insulation layer may be anisotropically etched to form a preliminary first interface insulation layer pattern 220, a preliminary ferroelectric layer pattern 222, and a preliminary second interface insulation layer pattern 224 sequentially stacked on the sidewall of the first trench 216.

A channel layer 226 may be conformally formed on the surface of the preliminary second interface insulation layer pattern 224, the bottom of the first trench 216, and the upper surface of the mold structure 214.

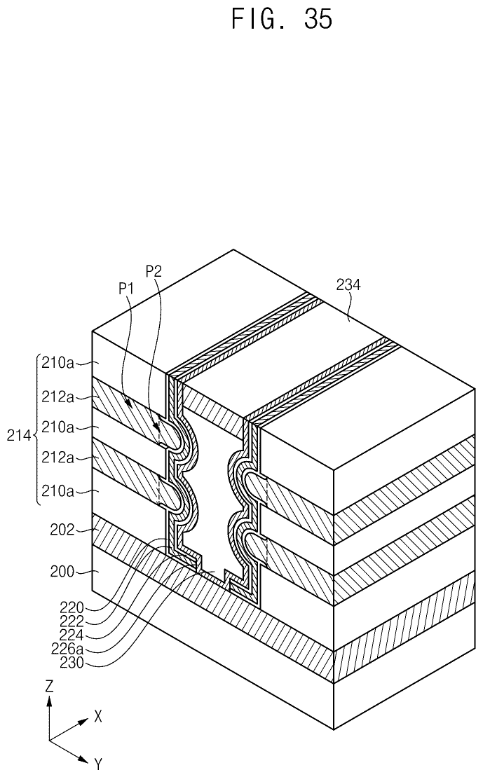

Referring to FIG. 35, a filling insulation layer may be formed on the channel layer 226 to completely fill the first trench 216. Thereafter, the filling insulation layer and the channel layer 226 may be planarized until an upper surface of the mold structure 214 is exposed to form a preliminary first insulation structure 230 and a preliminary channel layer pattern 226a.

Thereafter, an upper portion of the preliminary first insulation structure 230 may be partially removed to form an upper recess. The preliminary channel layer pattern 226a may be exposed by/on the sidewall of the upper recess. A conductive material may fill the upper recess to form a preliminary upper conductive pattern 234.

The processes described above may be the same or substantially the same as those described with reference to FIGS. 19 to 21.

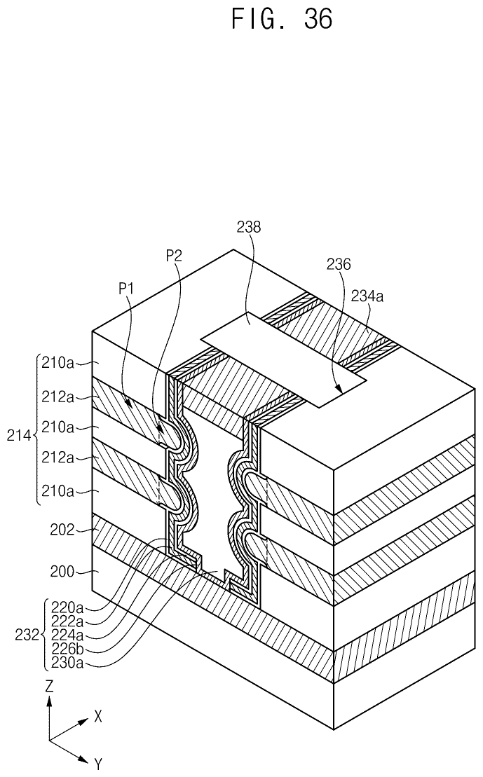

Referring to FIG. 36, a separation opening 236 may be formed through the preliminary first insulation structure 230, the preliminary channel layer pattern 226a, the preliminary second interface insulation layer pattern 224, the preliminary ferroelectric layer pattern 222, the preliminary first interface insulation layer pattern 220, and the preliminary upper conductive pattern 234 within the first trench and a mold structure 214 in the vertical direction Z. The separation opening 236 may extend to the upper portion of the source line 202 in a vertical direction.

A plurality of separation openings 236 may include portions overlapping the first trench 216, and may be spaced apart from each other in the first direction X. The preliminary first interface insulation layer pattern 220, the preliminary ferroelectric layer pattern 222, the preliminary second interface insulation layer pattern 224, the preliminary channel layer pattern 226a, and the preliminary first insulation structure 230 may be separated by the separation openings 236, so that a channel structure 232 including the first interface insulation layer pattern 220a, the ferroelectric layer pattern 222a, the second interface insulation layer pattern 224a, the channel layer pattern 226b, and the first insulation structure 230a may be formed in the first trench 216. In addition, the preliminary upper conductive pattern 234 may be separated to form the upper conductive pattern 234a.

An insulation material may fill the separation opening 236 to form a first separation pattern 238.

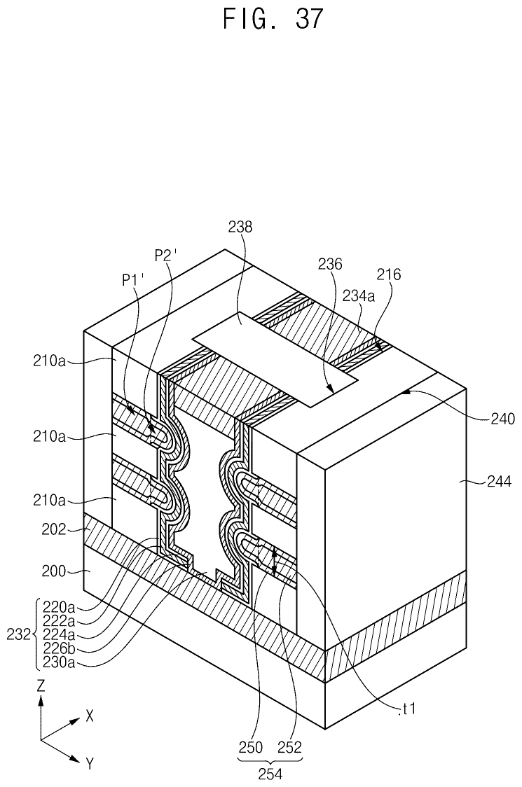

Referring to FIG. 37, a second trench 240 may be formed through the mold structure 214. The second trench 240 may extend in the vertical direction Z to at least an inside of a lowermost insulation layer pattern. The second trench 240 may extend, e.g., lengthwise, in the first direction X, and a plurality of second trenches 240 may be spaced apart from the channel structure 232.

The insulation layer patterns 210a and the sacrificial layer patterns 212a may be exposed by the second trench 240.

The sacrificial layer patterns 212a exposed by/on the sidewall of the second trench 240 may be selectively removed. Therefore, a gap may be formed between the insulation layer patterns 210a in the vertical direction Z. The gap may extend, e.g., lengthwise, in the first direction.

Thereafter, a gate pattern 254 may be formed in the gap. The gate pattern 154 may include a barrier metal pattern 250 and a metal pattern 252.

The first portion P1 of the sacrificial layer pattern 212a may correspond to a first portion P1′ of the gate pattern 254, and the second portion P2 of the sacrificial layer pattern 212a may correspond to a second portion P2′ of the gate pattern 254.

The first portion P1′ of the gate pattern 254 may be interposed between the insulation layer patterns 210a, and an upper surface and a lower surface of the gate pattern 254 may contact respective insulation layer patterns 210a. A surface of the second portion P2′ of the gate pattern 254 may be exposed by the first trench 216 or contact the first interface insulation layer pattern 220a, and the second portion P2′ of the gate pattern 254 may have a thickness, e.g., in a vertical direction, less than a thickness of the first portion P1′ of the gate pattern 254, e.g., in the vertical direction.

A second separation pattern 244 may be formed in the second trench 240.

Thereafter, an upper insulating interlayer may be formed on the second separation pattern 244, the insulation layer pattern 210a, the channel structure 232, and the upper conductive pattern 234a.

A bit line contact may be formed through the upper insulating interlayer. The bit line contact may be electrically connected to the upper conductive pattern 234a. A bit line contacting the bit line contact may be formed on the upper insulating interlayer.

By the above processes, a vertical semiconductor device may be manufactured.

The vertical semiconductor device according to example embodiments may be used as memories included in electronic products such as a mobile device, a memory card, and a computer.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the present inventive concepts have been shown and described with reference to example embodiments thereof, it will be understood by those of ordinary skill in the art that various changes in form and details may be made thereto without departing from the scope of the present invention as set forth by the following claims.

What is claimed is:

1. A semiconductor device, comprising:
insulation layer patterns on a substrate, the insulation layer patterns being spaced apart from each other in a vertical direction perpendicular to a surface of the substrate;
gate patterns interposed between the insulation layer patterns in the vertical direction, each of the gate patterns having a first portion contacting the insulation layer patterns and a second portion non-contacting the insulation layer patterns, wherein the second portion of each of the gate patterns protrudes from sidewalls of the insulation layer patterns, and the second portion of each of the gate patterns has a thickness less than a thickness of the first portion of each of the gate patterns; and
a first interface insulation layer pattern, a ferroelectric layer pattern, and a channel layer pattern sequentially stacked on the sidewalls of the insulation layer patterns and surfaces of the second portions of the gate patterns,
wherein the first interface insulation layer pattern, the ferroelectric layer pattern and the channel layer pattern are disposed along surface profiles of the sidewalls of the insulation layer patterns and the second portions of the gate patterns.

2. The semiconductor device of claim 1, further comprising a second interface insulation layer pattern between the ferroelectric layer pattern and the channel layer pattern.

3. The semiconductor device of claim 1, wherein an upper surface of the second portion of a gate pattern is lower than an upper surface of the first portion of the gate pattern, and
a lower surface of the second portion of the gate pattern is higher than a lower surface of the first portion of the gate pattern.

4. The semiconductor device of claim 1, wherein an edge of the second portion of a gate pattern has a rounded shape.

5. The semiconductor device of claim 1, wherein a stacked structure of the first interface insulation layer pattern, the ferroelectric layer pattern, and the channel layer pattern disposed on the second portion of a gate pattern protrudes laterally more than the stacked structure of the first interface insulation layer pattern, the ferroelectric layer pattern, and the channel layer pattern disposed on the sidewalls of the insulation layer patterns.

6. The semiconductor device of claim 1, wherein a boundary between the first portion of a gate pattern and the second portion of the gate pattern is positioned in a gap between the insulation layer patterns in the vertical direction.

7. A semiconductor device, comprising:
a first stacked structure including insulation layer patterns and gate patterns alternately and repeatedly disposed on a substrate, the first stacked structure including a first hole passing through the insulation layer patterns and gate patterns;
a first interface insulation layer pattern and a ferroelectric layer pattern sequentially stacked along profiles of sidewalls of the insulation layer patterns and surfaces of the gate patterns exposed by the first hole;
a channel layer pattern on the ferroelectric layer pattern and a bottom of the first hole; and
an insulation structure on the channel layer pattern, the insulation structure filling the first hole,
wherein each of the gate patterns includes a first portion contacting the insulation layer patterns and a second portion non-contacting the insulation layer patterns, and the second portion protrudes toward an inside of the first hole more than the sidewalls of the insulation layer patterns exposed by the first hole; and
wherein a boundary between the first portion of a gate pattern and the second portion of the gate pattern is positioned in a gap between insulation layer patterns.

8. The semiconductor device of claim 7, further comprising a second interface insulation layer pattern between the ferroelectric layer pattern and the channel layer pattern.

9. The semiconductor device of claim 7, wherein a thickness of the second portion of the gate pattern is less than a thickness of the first portion of the gate pattern.

10. The semiconductor device of claim 7, wherein an upper surface of the second portion of the gate pattern is lower than an upper surface of the first portion of the gate pattern, and a lower surface of the second portion of the gate pattern is higher than a lower surface of the first portion of the gate pattern.

11. The semiconductor device of claim 7, wherein an edge of the second portion of the gate pattern has a rounded shape.

12. The semiconductor device of claim 7, wherein a second stacked structure of the first interface insulation layer pattern, the ferroelectric layer pattern, and the channel layer pattern disposed on the second portion of the gate pattern protrudes toward the inside of the first hole more than the second stacked structure of the first interface insulation layer pattern, the ferroelectric layer pattern, and the channel layer pattern disposed on the sidewalls of the insulation layer patterns.

13. The semiconductor device of claim 7, wherein a portion of the insulation structure facing an insulation layer pattern has a first width, and a portion of the insulation structure facing the gate pattern has a second width less than the first width.

14. The semiconductor device of claim 13, wherein the second width of the insulation structure gradually decreases and then gradually increases in a direction moving downward along a vertical direction.

15. The semiconductor device of claim 7, wherein the gate pattern includes a metal.

16. The semiconductor device of claim 7, wherein the channel layer pattern includes a protruding portion toward the inside of the first hole, the protruding portion formed on a surface of the second portion of the gate pattern protruding toward inside of the first hole, and a surface area of the protruding portion of the channel layer pattern is greater than a surface area of the second portion of the gate pattern contacting the first interface insulation layer pattern.

17. The semiconductor device of claim 7, wherein the channel layer pattern surrounds an upper portion, a sidewall portion, and a lower portion of the second portion of the gate pattern.

18. A semiconductor device, comprising:
a source line on a substrate;
a stacked structure including insulation layer patterns and gate patterns alternately and repeatedly stacked on the source line, the stacked structure including an opening passing through the insulation layer patterns and the gate patterns, each of the gate patterns including a first portion contacting the insulation layer patterns and a second portion non-contacting the insulation layer patterns, wherein the second portion protrudes toward an inside of the opening more than sidewalls of the insulation layer patterns exposed by the opening;
a first interface insulation layer pattern and a ferroelectric layer pattern sequentially stacked on the sidewalls of the insulation layer patterns and surfaces of the gate patterns exposed by the opening;
a channel layer pattern on the ferroelectric layer pattern and a bottom of the opening; and
an insulation structure on the channel layer pattern to fill the opening,
wherein a thickness of the second portion of a gate pattern is less than a thickness of the first portion of the gate pattern, and an edge of the second portion of the gate pattern has a rounded shape,
wherein the first interface insulation layer pattern, the ferroelectric layer pattern and the channel layer pattern disposed on the second portion of the gate pattern include protruding portions toward the inside of the opening, and the protruding portions are formed on a surface of the second portion of the gate pattern protruding toward the inside of the opening.

19. The semiconductor device of claim 18, the opening having a hole shape or a trench shape extending in a horizontal direction.

20. The semiconductor device of claim 18, wherein a boundary between the first portion of the gate pattern and the second portion of the gate pattern is positioned in a gap between the insulation layer patterns in a vertical direction.
